(19) United States
(12) Patent Application Publication
(10) Pub. No.: US 2025/0098287 A1
(43) Pub. Date: Mar. 20, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Shimpei KAMIYA, Tokyo (JP); Munenori IKEDA, Tokyo (JP); Kenji HARADA, Tokyo (JP)

(73) Assignee: Mitsubishi Electric Corporation, Tokyo (JP)

(21) Appl. No.: 18/761,979

(22) Filed: Jul. 2, 2024

(30) Foreign Application Priority Data
Sep. 14, 2023 (JP) 2023-149130

(51) Int. Cl. H01L 27/06; H01L 29/06; H01L 29/66; H01L 29/739; H01L 29/861

(52) U.S. Cl. CPC H10D 84/617; H10D 8/00; H10D 12/038; H10D 12/481; H10D 62/107; H10D 62/116

(57) ABSTRACT

A semiconductor device is a semiconductor device in which a transistor is formed on a semiconductor substrate including a first main surface and a second main surface, a transistor region of the semiconductor substrate includes an n-type first semiconductor layer, a p-type second semiconductor layer provided closer to the first main surface than the first semiconductor layer, an n-type third semiconductor layer provided closer to a first main surface side than the second semiconductor layer, a trench gate that penetrates the third semiconductor layer and the second semiconductor layer in a thickness direction from the first main surface and reaches an inside of the first semiconductor layer, and an interlayer insulating film provided on the trench gate. The interlayer insulating film includes at least one narrow width portion in which a length in a width direction intersecting an extending direction of the trench gate in planar view is partially narrowed.

### BACKGROUND OF THE INVENTION

### Field of the Invention

The present disclosure relates to a semiconductor device, and particularly to a semiconductor device including a trench gate.

### Description of the Background Art

Japanese Patent Application Laid-Open No. 2008-91491 discloses, as an example of a switching device including the trench gate, an insulated gate bipolar transistor (IGBT) in which an emitter layer connected to an emitter electrode is formed in a stripe shape in a direction intersecting an extending direction of the trench gate in FIG. 1.

An interlayer insulating film is formed above the trench gate, and a plurality of contact regions are formed between adjacent trench gates along the extending direction of the trench gate.

A length in a left-right direction, namely, a width of the interlayer insulating film is formed so as to be larger at a portion where the emitter layer is provided than at a portion where the emitter layer is not provided, and a planar view shape of the interlayer insulating film is a shape in which irregularities are repeated in the left-right direction along the trench gate.

As described above, in the conventional technique, a contact portion between the emitter electrode and the emitter layer is narrowed by increasing the width of the interlayer insulating film at the portion where the emitter layer is provided, and a configuration in which current is prevented to improve reliability even when a large current flows during generation of a short circuit or the like is adopted.

In such a conventional semiconductor device, because the contact portion between the emitter electrode and the emitter layer is narrowed, a current path in a state where the IGBT is turned on is also narrowed, and thus there is a problem that a loss of the transistor due to an increase in on-resistance increases.

### SUMMARY

The present disclosure relates to a semiconductor device, and an object of the present disclosure is to provide a semiconductor device in which a variation in breakdown resistance under conditions such as a gate breakdown resistance, a reverse bias safe operating area (RBSOA), and a short circuit test in which a large current flows to improve the reliability without narrowing the current path in the state where the IGBT is turned on.

A semiconductor device according to the present disclosure is a semiconductor device in which a transistor is formed on a semiconductor substrate including a first main surface and a second main surface, in which the semiconductor device includes a transistor region in which the transistor is formed, the transistor region includes a first main electrode electrically connected to the first main surface, a second main electrode electrically connected to the second main surface, a first semiconductor layer of a first conductivity type, a second semiconductor layer of a second conductivity type provided closer to the first main surface than the first semiconductor layer, a third semiconductor layer of the first conductivity type provided closer to the first main surface than the second semiconductor layer and electrically connected to the first main electrode, a trench gate that penetrates the third semiconductor layer and the second semiconductor layer in a thickness direction from the first main surface and reaches an inside of the first semiconductor layer, and an interlayer insulating film provided on the trench gate, the interlayer insulating film includes at least one narrow width portion in which a length in a width direction intersecting an extending direction of the trench gate in planar view is partially narrowed, and the length of the narrow width portion in the width direction is longer than the length of the trench gate in the width direction.

According to the semiconductor device of the present disclosure, the interlayer insulating film includes at least one narrow width portion, so that the semiconductor device in which the variation in the breakdown resistance under the condition that the large current flows is reduced to improve the reliability without narrowing the current path in the state where the transistor is turned on can be provided.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIGS. 1 and 2 are plan views each illustrating a semiconductor device that is an RC-IGBT;

FIG. 3 is a partial plan view illustrating an IGBT region in the RC-IGBT;

FIGS. 4 and 5 are partially sectional views each illustrating the IGBT region in the RC-IGBT;

FIG. 6 is a partial plan view illustrating a diode region in the RC-IGBT;

FIGS. 7 and 8 are partially sectional views each illustrating a diode region in the RC-IGBT;

FIG. 9 is a sectional view illustrating a boundary portion between the IGBT region and the diode region of the RC-IGBT;

FIGS. 10 and 11 are sectional views illustrating a boundary portion between the IGBT region and a termination region of the RC-IGBT;

FIGS. 12 to 22 are sectional views for explaining a method of manufacturing the RC-IGBT;

FIG. 23 is a partial plan view illustrating a configuration of an RC-IGBT according to a first preferred embodiment;

FIG. 24 is an overall plan view illustrating a configuration of an RC-IGBT according to a second preferred embodiment;

FIGS. 25 and 26 are sectional views illustrating the configuration of the RC-IGBT of the second preferred embodiment;

FIG. 27 is a view illustrating the configuration of the RC-IGBT of the second preferred embodiment;

FIGS. 28 to 35 are sectional views illustrating a process for manufacturing the RC-IGBT of the second preferred embodiment;

FIG. 36 is a partial plan view illustrating a configuration of an RC-IGBT according to a third preferred embodiment;

FIG. 37 is an enlarged view illustrating a narrow width portion of the RC-IGBT of the third preferred embodiment;

FIG. 38 is a sectional view illustrating the narrow width portion of the RC-IGBT of the third preferred embodiment;

FIG. 39 is a partial plan view illustrating a configuration of an RC-IGBT according to a fourth preferred embodiment;

FIG. 40 is a flowchart illustrating a method of manufacturing an RC-IGBT according to a fifth preferred embodiment;

FIGS. 41 to 45 are views illustrating the method of manufacturing the RC-IGBT of the fifth preferred embodiment;

FIG. 46 is a flowchart illustrating another method of manufacturing the RC-IGBT of the fifth preferred embodiment;

FIG. 47 is a view illustrating an exposure pattern when a resist material is a positive type;

FIG. 48 is a view illustrating a pattern of a resist mask obtained by exposing a positive resist material; and

FIGS. 49 to 51 are sectional views each illustrating another method of manufacturing a step.

### DESCRIPTION OF THE PREFERRED EMBODIMENTS

### Introduction

In the following description, an n-type and a p-type represent a conductivity type of a semiconductor, and in the present disclosure, a first conductivity type is described as the n-type and a second conductivity type is described as the p-type. However, the first conductivity type may be the p-type and the second conductivity type may be the n-type. In addition, an n⁻-type indicates that an impurity concentration is lower than the n-type, and an n⁺-type indicates that the impurity concentration is higher than the n-type. Similarly, a p⁻-type indicates that the impurity concentration is lower than the p-type, and a p⁺-type indicates that the impurity concentration is higher than p-type.

In addition, drawings are schematically illustrated, and a mutual relationship between sizes and positions of images illustrated in different drawings is not necessarily accurately described, and can be appropriately changed. In the following description, the same components are denoted by the same reference numeral, and it is assumed that names and functions of the same components are also similar. Accordingly, sometimes a detailed description thereof is omitted.

In addition, in the following description, terms meaning specific positions and directions such as “upper”, “lower”, “side”, “front”, and “back” may be used, but these terms are used for convenience to facilitate understanding of contents of the embodiments and are not related to directions when actually implemented.

Prior to the description of the preferred embodiments, a reverse conducting IGBT (RC-IGBT) in which an IGBT and a free wheeling diode (FWD) are provided on a common semiconductor substrate will be described below.

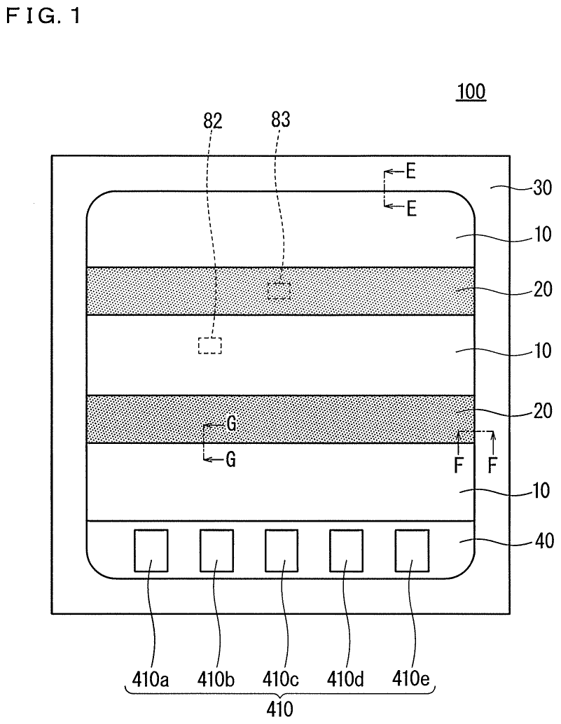

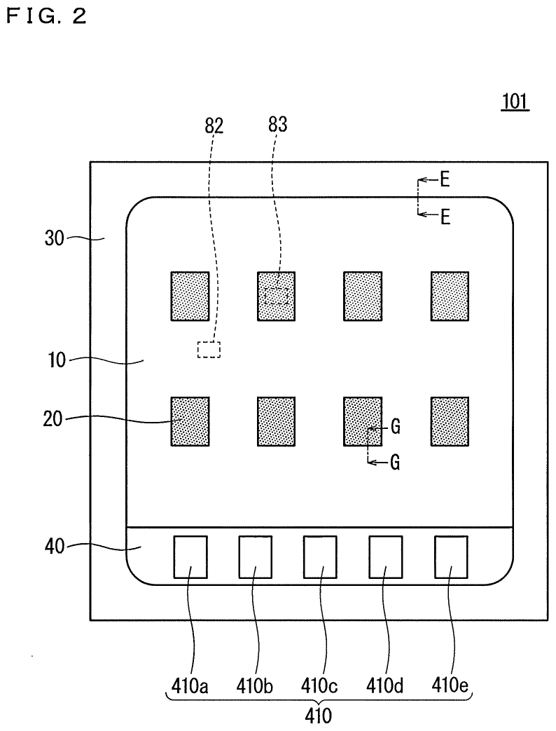

FIG. 1 is a plan view illustrating a semiconductor device that is an RC-IGBT. FIG. 2 is a plan view illustrating a semiconductor device that is an RC-IGBT having another configuration. A semiconductor device 100 in FIG. 1 is provided while an IGBT region 10 and a diode region 20 are arranged in a stripe shape, and may be simply referred to as a “stripe type”. A semiconductor device 101 in FIG. 2 is provided while a plurality of diode regions 20 in a longitudinal direction and a lateral direction, and the IGBT region 10 is provided around the diode region 20, and may be simply referred to as an “island type”.

### (1) Overall Planar Structure of Stripe Type

In FIG. 1, the semiconductor device 100 includes the IGBT region 10 and the diode region 20 in one semiconductor device. The IGBT region 10 and the diode region 20 extend from one end side to the other end side of the semiconductor device 100, and are alternately provided in a stripe shape in a direction orthogonal to the extending direction of the IGBT region 10 and the diode region 20. In FIG. 1, three IGBT regions 10 and two diode regions 20 are illustrated, and all the diode regions 20 are sandwiched between the IGBT regions 10. However, the numbers of the IGBT regions 10 and the diode regions 20 are not limited thereto, and the number of the IGBT regions 10 may be equal to and greater than three and equal to or smaller than three, and the number of the diode regions 20 may be equal to and greater than two and equal to or smaller than two. In addition, locations of the IGBT region 10 and the diode region 20 in FIG. 1 may be interchanged, or all the IGBT regions 10 may be sandwiched between the diode regions 20. In addition, the IGBT region 10 and the diode region 20 may be provided adjacent to each other one by one.

As illustrated in FIG. 1, a pad region 40 is provided adjacent to the IGBT region 10 on a lower side of a page. The pad region 40 is a region where a control pad 410 controlling the semiconductor device 100 is provided. The IGBT region 10 and the diode region 20 are collectively referred to as a cell region. A termination region 30 is provided around a combined region of the cell region and the pad region 40 in order to maintain a withstand voltage of the semiconductor device 100. A known withstand voltage holding structure can be appropriately selected and provided in the termination region 30. For example, the withstand voltage holding structure may be configured by providing a field limiting ring (FLR) surrounding the cell region with a p-type termination well layer of a p-type semiconductor and a variation of lateral doping (VLD) surrounding the cell region with a p-type well layer with a concentration gradient on the first main surface side that is a front surface side of the semiconductor device 100, and the number of ring-shaped p-type termination well layers used for the FLR and the concentration distribution used for the VLD may be appropriately selected according to the withstand voltage design of the semiconductor device 100. In addition, the p-type termination well layer may be provided over substantially the entire pad region 40, and an IGBT cell and a diode cell may be provided in the pad region 40.

For example, the control pad 410 may be a current sense pad 410a, a Kelvin emitter pad 410b, a gate pad 410c, and temperature sense diode pads 410d, 410e. The current sense pad 410a is the control pad detecting current flowing through the cell region of the semiconductor device 100, and is the control pad electrically connected to IGBT cells or diode cells in a part of the cell region such that, when the current flows through the cell region of the semiconductor device 100, the current of 1/several to 1/several tens of thousands of times of the current flowing through the entire cell region flows.

The Kelvin emitter pad 410b and the gate pad 410c are control pads to which a gate drive voltage controlling on and off of the semiconductor device 100 is applied. The Kelvin emitter pad 410b is electrically connected to a p-type base layer of the IGBT cell, and the gate pad 410c is electrically connected to a gate trench electrode of the IGBT cell. The Kelvin emitter pad 410b and the p-type base layer may be electrically connected through a p⁺-type contact layer. The temperature sense diode pads 410d, 410e are control pads electrically connected to an anode and a cathode of a temperature sense diode provided in the semiconductor device 100. The voltage between the anode and the cathode of the temperature sense diode (not illustrated) provided in the cell region is measured to measure the temperature at the semiconductor device 100.

### (2) Overall Planar Structure of Island Type

In FIG. 2, the semiconductor device 101 includes the IGBT region 10 and the diode region 20 in one semiconductor device. A plurality of diode regions 20 are arranged side by side in the longitudinal direction and the lateral direction in the semiconductor device, and the diode region 20 is surrounded by the IGBT region 10. That is, the plurality of diode regions 20 are provided in an island shape in the IGBT region 10. In FIG. 2, the diode regions 20 are provided in a matrix of 4 columns in the horizontal direction on the page and 2 rows in the upper limit direction on the page. However, the number and arrangement of the diode regions 20 are not limited to this, and one or a plurality of diode regions 20 may be provided in the IGBT region 10 in an interspersed manner, and each diode region 20 may be surrounded by the IGBT region 10.

As illustrated in FIG. 2, the pad region 40 is provided adjacent to the lower side of the page of the IGBT region 10. The pad region 40 is a region where the control pad 410 controlling the semiconductor device 101 is provided. The IGBT region 10 and the diode region 20 are collectively referred to as a cell region. The termination region 30 is provided around the combined region of the cell region and the pad region 40 in order to maintain the withstand voltage of the semiconductor device 101. A known withstand voltage holding structure can be appropriately selected and provided in the termination region 30. For example, the withstand voltage holding structure may be configured by providing the field limiting ring (FLR) surrounding the region obtained by combining the cell region and the pad region 40 with the p-type termination well layer of the p-type semiconductor and the variation of lateral doping (VLD) surrounding the cell region with the p-type well layer with the concentration gradient on the first main surface side that is the front surface side of the semiconductor device 101, and the number of ring-shaped p-type termination well layers used for the FLR and the concentration distribution used for the VLD may be appropriately selected according to the withstand voltage design of the semiconductor device 101. In addition, the p-type termination well layer may be provided over substantially the entire pad region 40, and an IGBT cell and a diode cell may be provided in the pad region 40.

For example, the control pad 410 may be a current sense pad 410a, a Kelvin emitter pad 410b, a gate pad 410c, and temperature sense diode pads 410d, 410e. The current sense pad 410a is the control pad detecting the current flowing through the cell region of the semiconductor device 101, and is the control pad electrically connected to IGBT cells or diode cells in a part of the cell region such that, when the current flows through the cell region of the semiconductor device 101, the current of 1/several to 1/several tens of thousands of times of the current flowing through the entire cell region flows.

The Kelvin emitter pad 410b and the gate pad 410c are control pads to which the gate drive voltage controlling on and off of the semiconductor device 101 is applied. The Kelvin emitter pad 410b is electrically connected to the p-type base layer and the n⁺-type source layer of the IGBT cell, and the gate pad 410c is electrically connected to the gate trench electrode of the IGBT cell. The Kelvin emitter pad 410b and the p-type base layer may be electrically connected through a p⁺-type contact layer. The temperature sense diode pads 410d, 410e are control pads electrically connected to the anode and the cathode of the temperature sense diode provided in the semiconductor device 101. The voltage between the anode and the cathode of the temperature sense diode (not illustrated) provided in the cell region is measured to measure the temperature at the semiconductor device 101.

### (3) General Structure of IGBT Region 10

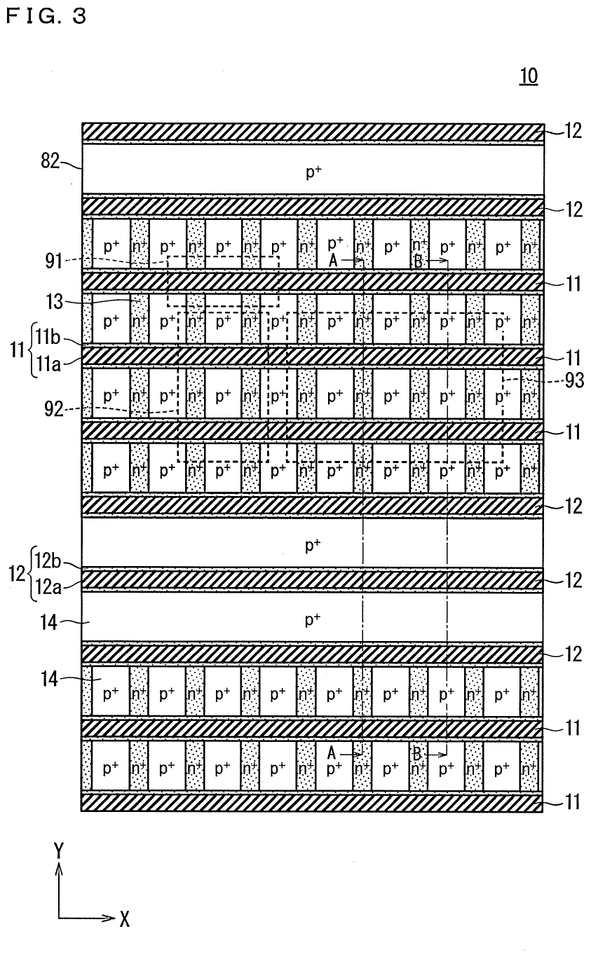

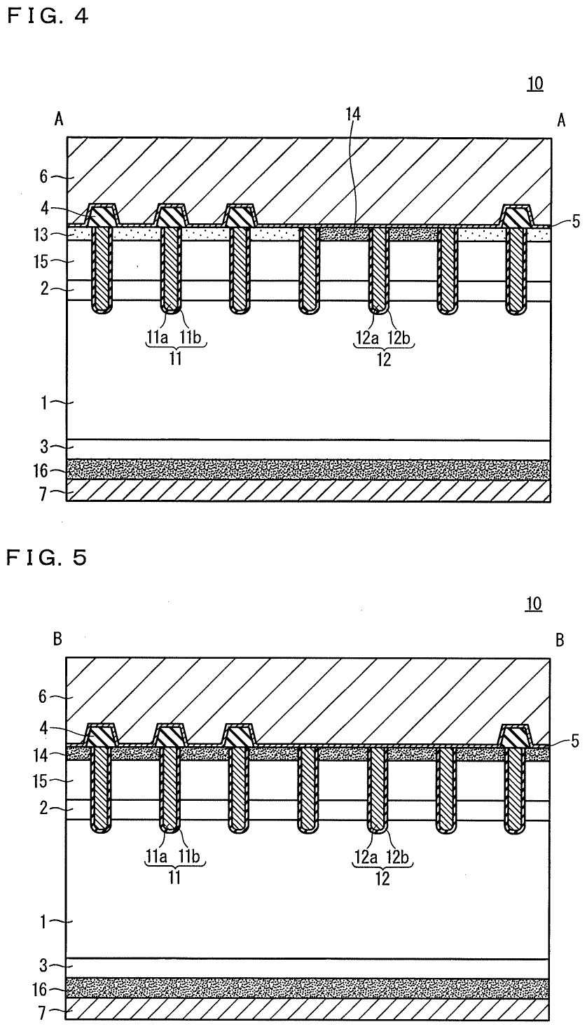

FIG. 3 is a partially enlarged plan view illustrating a configuration of the IGBT region of the semiconductor device that is the RC-IGBT. FIGS. 4 and 5 are sectional views illustrating a configuration of the IGBT region of the semiconductor device that is the RC-IGBT. FIG. 3 is an enlarged view illustrating a region 82 surrounded by a broken line in the semiconductor device 100 in FIG. 1 or the semiconductor device 101 illustrated in FIG. 2. FIG. 4 is a sectional view illustrating the semiconductor device 100 in FIG. 3 or the semiconductor device 101 in FIG. 2 taken along a broken line A-A in an arrow direction, and FIG. 5 is a sectional view illustrating the semiconductor device 100 or the semiconductor device 101 in FIG. 3 taken along a broken line B-B in the arrow direction.

As illustrated in FIG. 3, in the IGBT region 10, an active trench gate 11 and a dummy trench gate 12 are provided in a stripe shape. In the semiconductor device 100, the active trench gate 11 and the dummy trench gate 12 extend in the longitudinal direction of the IGBT region 10, and the longitudinal direction of the IGBT region 10 is the longitudinal direction of the active trench gate 11 and the dummy trench gate 12. On the other hand, in the semiconductor device 101, there is no particular distinction between the longitudinal direction and the lateral direction in the IGBT region 10, but the lateral direction in the drawing may be the longitudinal direction of the active trench gate 11 and the dummy trench gate 12, and the vertical direction in the drawing may be the longitudinal direction of the active trench gate 11 and the dummy trench gate 12.

The active trench gate 11 is configured such that a gate trench electrode 11a is provided in a trench formed in the semiconductor substrate through a gate trench insulating film 11b. The dummy trench gate 12 is configured by providing a dummy trench electrode 12a in a trench formed in the semiconductor substrate through a dummy trench insulating film 12b. The gate trench electrode 11a of the active trench gate 11 is electrically connected to the gate pad 410c. The dummy trench electrode 12a of the dummy trench gate 12 is electrically connected to the emitter electrode provided on the first main surface of the semiconductor device 100 or the semiconductor device 101.

An n⁺-type source layer 13 is provided on both sides in the width direction of the active trench gate 11 so as to be in contact with the gate trench insulating film 11b. The n⁺-type source layer 13 is a semiconductor layer containing, for example, arsenic or phosphorus as an n-type impurity, and the concentration of the n-type impurity is 1.0×10¹⁷/cm³ to 1.0×10²⁰/cm³. The n⁺-type source layer 13 is provided alternately with a p⁺-type contact layer 14 along the extending direction of the active trench gate 11. The p⁺-type contact layer 14 is also provided between two adjacent dummy trench gates 12. The p⁺-type contact layer 14 is a semiconductor layer containing, for example, boron or aluminum as a p-type impurity, and the concentration of the p-type impurity is 1.0×10¹⁵/cm³ to 1.0×10²⁰/cm³.

As illustrated in FIG. 3, in the IGBT region 10 of the semiconductor device 100 or the semiconductor device 101, three dummy trench gates 12 are arranged next to three active trench gates 11, and three active trench gates 11 are arranged next to three dummy trench gates 12. The IGBT region 10 has a configuration in which a set of active trench gates 11 and a set of dummy trench gates 12 are alternately arranged as described above. In FIG. 3, the number of active trench gates 11 included in one set of active trench gates 11 is 3, but may be equal to or greater than 1. In addition, the number of dummy trench gates 12 included in a set of one dummy trench gate 12 may be equal to or greater than 1, and the number of dummy trench gates 12 may be zero. That is, all the trenches provided in the IGBT region 10 may be used as the active trench gate 11.

FIG. 4 is a sectional view illustrating the semiconductor device 100 or the semiconductor device 101 taken along a broken line A-A in FIG. 3 in the arrow direction, and is a sectional view of the IGBT region 10. The semiconductor device 100 or the semiconductor device 101 includes an n⁻-type drift layer 1 that is a second semiconductor layer made of a semiconductor substrate. The n⁻-type drift layer 1 is a semiconductor layer containing, for example, the arsenic or the phosphorus as an n-type impurity, and the concentration of the n-type impurity is 1.0×10¹²/cm³ to 1.0×10¹⁵/cm³. In FIG. 4, the semiconductor substrate is in a range from the n⁺-type source layer 13 and the p⁺-type contact layer 14 to a p-type collector layer 16. In FIG. 4, the upper end of the paper surface of the n⁺-type source layer 13 and the p⁺-type contact layer 14 is referred to as a first main surface of the semiconductor substrate, and the lower end of the paper surface of the p-type collector layer 16 is referred to as a second main surface of the semiconductor substrate. The first main surface of the semiconductor substrate is a main surface on the front surface side of the semiconductor device 100, and the second main surface of the semiconductor substrate is a main surface on the back surface side of the semiconductor device 100. The semiconductor device 100 includes the n⁻-type drift layer 1 between the first main surface and the second main surface opposed to the first main surface in the IGBT region 10 that is a cell region.

As illustrated in FIG. 4, in the IGBT region 10, an n-type carrier accumulation layer 2 having a higher n-type impurity concentration than the n⁻-type drift layer 1 is provided on the first main surface side of the n⁻-type drift layer 1. The n-type carrier accumulation layer 2 is a semiconductor layer containing, for example, the arsenic or the phosphorus as the n-type impurity, and the concentration of the n-type impurity is 1.0×10¹³/cm³ to 1.0×10¹⁷/cm³. The semiconductor device 100 or the semiconductor device 101 may have a configuration in which the n⁻-type drift layer 1 is also provided in the region of the n-type carrier accumulation layer 2 in FIG. 4 without providing the n-type carrier accumulation layer 2. The provision of the n-type carrier accumulation layer 2 can reduce an energization loss when the current flows in the IGBT region 10. The n-type carrier accumulation layer 2 and the n⁻-type drift layer 1 may be collectively referred to as a drift layer.

The n-type carrier accumulation layer 2 is formed by ion-implanting the n-type impurity into a semiconductor substrate configuring the n⁻-type drift layer 1 and then diffusing the n-type impurity implanted by annealing into the semiconductor substrate as the n⁻-type drift layer 1.

A p-type base layer 15 is provided on the first main surface side of the n-type carrier accumulation layer 2. The p-type base layer 15 is a semiconductor layer containing, for example, boron or aluminum as the p-type impurity, and the concentration of the p-type impurity is 1.0×10¹²/cm³ to 1.0×10¹⁹/cm³. The p-type base layer 15 is in contact with the gate trench insulating film 11b of the active trench gate 11. On the first main surface side of the p-type base layer 15, the n⁺-type source layer 13 is provided in contact with the gate trench insulating film 11b of the active trench gate 11, and the p⁺-type contact layer 14 is provided in the remaining region. The n⁺-type source layer 13 and the p⁺-type contact layer 14 configure the first main surface of the semiconductor substrate. The p⁺-type contact layer 14 is a region having a higher p-type impurity concentration than the p-type base layer 15, and when the p⁺-type contact layer 14 and the p-type base layer 15 are required to be distinguished from each other, they may be referred to individually, and the p⁺-type contact layer 14 and the p-type base layer 15 may be collectively referred to as a p-type base layer.

In the semiconductor device 100 or the semiconductor device 101, an n-type buffer layer 3 having a higher concentration of the n-type impurity than the n⁻-type drift layer 1 is provided on the second main surface side of the n-type drift layer 1. The n-type buffer layer 3 is provided to restrict punch-through of a depletion layer extending from the p-type base layer 15 to the second main surface side when the semiconductor device 100 is in an off-state. The n-type buffer layer 3 may be formed by, for example, implanting the phosphorus (P) or proton (H⁺), or implanting both the phosphorus (P) and the proton (H⁺). The concentration of the n-type impurity in the n-type buffer layer 3 is 1.0×10¹²/cm³ to 1.0×10¹⁸/cm³.

The semiconductor device 100 or the semiconductor device 101 may have a configuration in which the n⁻-type drift layer 1 is also provided in the region of the n-type buffer layer 3 in FIG. 4 without providing the n-type buffer layer 3. The n-type buffer layer 3 and the n⁻-type drift layer 1 may be collectively referred to as a drift layer.

In the semiconductor device 100 or the semiconductor device 101, the p-type

collector layer 16 is provided on the second main surface side of the n-type buffer layer 3. That is, the p-type collector layer 16 is provided between the n⁻-type drift layer 1 and the second main surface. The p-type collector layer 16 is a semiconductor layer containing, for example, boron or aluminum as a p-type impurity, and the concentration of the p-type impurity is 1.0×10¹⁶/cm³ to 1.0×10²⁰/cm³. The p-type collector layer 16 configures the second main surface of the semiconductor substrate. The p-type collector layer 16 is provided not only in the IGBT region 10 but also in the termination region 30, and a portion of the p-type collector layer 16 provided in the termination region 30 configures a p-type termination collector layer 16a. In addition, the p-type collector layer 16 may be provided so as to partially protrude from the IGBT region 10 to the diode region 20.

As illustrated in FIG. 4, the trench that penetrates the p-type base layer 15 from the first main surface of the semiconductor substrate and reaches the n⁻-type drift layer 1 is formed in the semiconductor device 100 or the semiconductor device 101. The gate trench electrode 11a is provided in the trench through the gate trench insulating film 11b to configure the active trench gate 11. The gate trench electrode 11a is opposite to the n⁻-type drift layer 1 through the gate trench insulating film 11b. The dummy trench electrode 12a is provided in the trench through the dummy trench insulating film 12b to configure the dummy trench gate 12. The dummy trench electrode 12a is opposite to the n⁻-type drift layer 1 through the dummy trench insulating film 12b. The gate trench insulating film 11b of the active trench gate 11 is in contact with the p-type base layer 15 and the n⁺-type source layer 13. When the gate drive voltage is applied to the gate trench electrode 11a, a channel is formed in the p-type base layer 15 that is in contact with the gate trench insulating film 11b of the active trench gate 11.

As illustrated in FIG. 4, an interlayer insulating film 4 is provided on the gate trench electrode 11a of the active trench gate 11. A barrier metal 5 is formed on the region of the first main surface of the semiconductor substrate where the interlayer insulating film 4 is not provided and on the interlayer insulating film 4. For example, the barrier metal 5 may be a conductor containing titanium (Ti), and may be titanium nitride or TiSi obtained by alloying titanium and silicon (Si). As illustrated in FIG. 4, the barrier metal 5 is in ohmic contact with the n⁺-type source layer 13, the p⁺-type contact layer 14, and the dummy trench electrode 12a, and is electrically connected to the n⁺-type source layer 13, the p⁺-type contact layer 14, and the dummy trench electrode 12a. An emitter electrode 6 is provided on the barrier metal 5. For example, the emitter electrode 6 may be formed of an aluminum alloy such as an aluminum silicon alloy (Al—Si-based alloy), or may be an electrode including a plurality of layers of metal films in which a plating film is formed on an electrode formed of an aluminum alloy by electroless plating or electrolytic plating. For example, the plating film formed by electroless plating or electrolytic plating may be a nickel (Ni) plating film. In addition, in the case of a fine region between adjacent interlayer insulating films 4 or the like and a region where favorable embedding cannot be obtained in the emitter electrode 6, tungsten having better embeddability than the emitter electrode 6 may be arranged in the fine region, and the emitter electrode 6 may be provided on the tungsten. The emitter electrode 6 may be provided on the n⁺-type source layer 13, the p⁺-type contact layer 14, and the dummy trench electrode 12a without providing the barrier metal 5. In addition, the barrier metal 5 may be provided only on the n-type semiconductor layer such as the n⁺-type source layer 13. The barrier metal 5 and the emitter electrode 6 may be collectively referred to as an emitter electrode. Although FIG. 4 illustrates a view in which the interlayer insulating film 4 is not provided on the dummy trench electrode 12a of the dummy trench gate 12, the interlayer insulating film 4 may be formed on the dummy trench electrode 12a of the dummy trench gate 12. When the interlayer insulating film 4 is formed on the dummy trench electrode 12a of the dummy trench gate 12, the emitter electrode 6 and the dummy trench electrode 12a may be electrically connected in another section.

A collector electrode 7 is provided on the second main surface side of the p-type collector layer 16. Similarly to the emitter electrode 6, the collector electrode 7 may be made of an aluminum alloy or an aluminum alloy and a plating film. The collector electrode 7 may have a configuration different from that of the emitter electrode 6. The collector electrode 7 is in ohmic contact with the p-type collector layer 16 and is electrically connected to the p-type collector layer 16.

FIG. 5 is a sectional view illustrating the semiconductor device 100 or the semiconductor device 101 taken along a broken line B-B in FIG. 3 in the arrow direction, and is a sectional view illustrating the IGBT region 10. The sectional view in the arrow direction taken along the broken line A-A in FIG. 4 is different from the sectional view in the arrow direction taken along the broken line B-B in FIG. 5 in that the n⁺-type source layer 13 provided on the first main surface side of the semiconductor substrate in contact with the active trench gate 11 is not seen. That is, as illustrated in FIG. 3, the n⁺-type source layer 13 is selectively provided on the first main surface side of the p-type base layer. The p-type base layer referred to herein is a p-type base layer in which the p-type base layer 15 and the p⁺-type contact layer 14 are collectively referred to.

### (4) General Structure of Diode Region 20

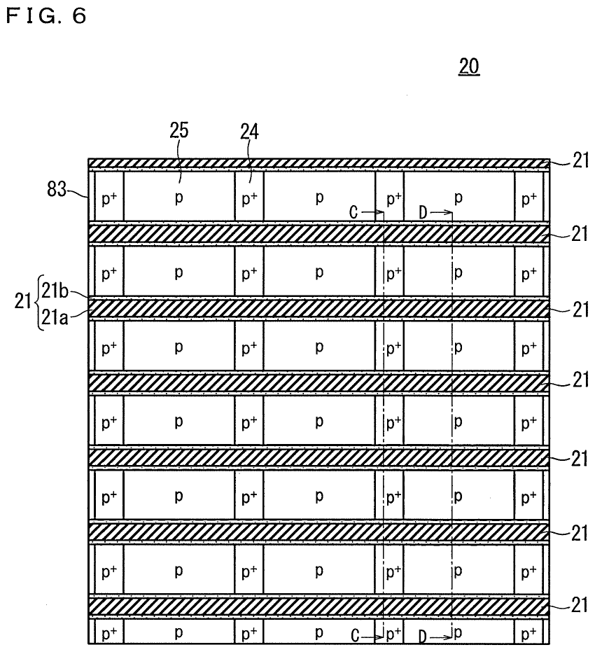

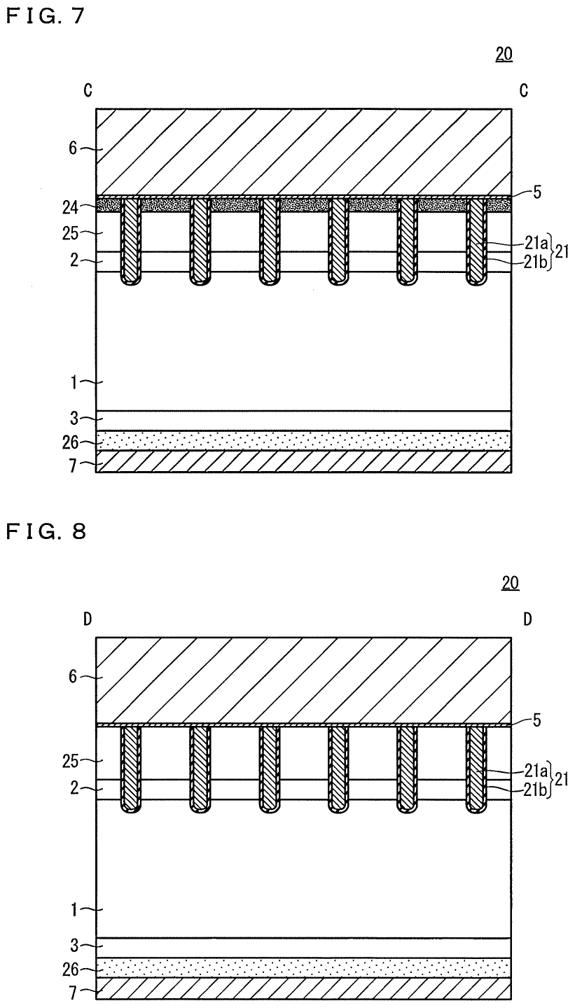

FIG. 6 is a partially enlarged plan view illustrating a configuration of the diode region of the semiconductor device that is the RC-IGBT. FIGS. 7 and 8 are sectional views illustrating a configuration of the diode region of the semiconductor device that is the RC-IGBT. FIG. 6 is an enlarged view illustrating a region 83 surrounded by the broken line in the semiconductor device 100 or the semiconductor device 101 in FIG. 1. FIG. 7 is a sectional view illustrating the semiconductor device 100 in FIG. 6 taken along a broken line C-C in the arrow direction. FIG. 8 is a sectional view illustrating the semiconductor device 100 in FIG. 6 taken along a broken line D-D in the arrow direction.

A diode trench gate 21 extends along the first main surface of the semiconductor device 100 or the semiconductor device 101 from one end side of the diode region 20, which is the cell region, toward the opposite end side. The diode trench gate 21 is configured by providing a diode trench electrode 21a in the trench formed in the semiconductor substrate of the diode region 20 through a diode trench insulating film 21b. The diode trench electrode 21a is opposite to the n⁻-type drift layer 1 through the diode trench insulating film 21b. A p⁺-type contact layer 24 and a p-type anode layer 25 as a third semiconductor layer are provided between the two adjacent diode trench gates 21. The p⁺-type contact layer 24 is a semiconductor layer containing, for example, boron or aluminum as the p-type impurity, and the concentration of the p-type impurity is 1.0×10¹⁵/cm³ to 1.0×10²⁰/cm³. The p-type anode layer 25 is a semiconductor layer containing, for example, boron or aluminum as the p-type impurity, and the concentration of the p-type impurity is 1.0×10¹²/cm³ to 1.0×10¹⁹/cm³. The p⁺-type contact layer 24 and the p-type anode layer 25 are alternately provided in the longitudinal direction of the diode trench gate 21.

FIG. 7 is a sectional view illustrating the semiconductor device 100 or the semiconductor device 101 taken along the broken line C-C in FIG. 6 in the arrow direction, and is a sectional view illustrating the diode region 20. The semiconductor device 100 or the semiconductor device 101 also includes the n⁻-type drift layer 1 made of the semiconductor substrate in the diode region 20 similarly to the IGBT region 10. The n⁻-type drift layer 1 of the diode region 20 and the n⁻-type drift layer 1 of the IGBT region 10 are continuously and integrally formed, and are formed of the same semiconductor substrate. In FIG. 7, the semiconductor substrate ranges from the p⁺-type contact layer 24 to an n⁺-type cathode layer 26 as the first semiconductor layer. In FIG. 7, the upper end of the page of the p⁺-type contact layer 24 is referred to as the first main surface of the semiconductor substrate, and the lower end of the page of the n⁺-type cathode layer 26 is referred to as the second main surface of the semiconductor substrate. The first main surface of the diode region 20 and the first main surface of the IGBT region 10 are flush, and the second main surface of the diode region 20 and the second main surface of the IGBT region 10 are flush.

As illustrated in FIG. 7, also in the diode region 20, similarly to the IGBT region 10, the n-type carrier accumulation layer 2 is provided on the first main surface side of the n⁻-type drift layer 1, and the n-type buffer layer 3 is provided on the second main surface side of the n⁻-type drift layer 1. The n-type carrier accumulation layer 2 and the n-type buffer layer 3 that are provided in the diode region 20 have the same configuration as the n-type carrier accumulation layer 2 and the n-type buffer layer 3 that are provided in the IGBT region 10. The n-type carrier accumulation layer 2 is not necessarily provided in the IGBT region 10 and the diode region 20, and the n-type carrier accumulation layer 2 may not be provided in the diode region 20 even when the n-type carrier accumulation layer 2 is provided in the IGBT region 10. Similarly to the IGBT region 10, the n⁻-type drift layer 1, the n-type carrier accumulation layer 2, and the n-type buffer layer 3 may be collectively referred to as a drift layer.

The p-type anode layer 25 is provided on the first main surface side of the n-type carrier accumulation layer 2. The p-type anode layer 25 is provided between the n−-type drift layer 1 and the first main surface. In the p-type anode layer 25, the p-type anode layer 25 and the p-type base layer 15 may be simultaneously formed by making the concentration of the p-type impurity the same as that of the p-type base layer 15 of the IGBT region 10. In addition, the concentration of the p-type impurity of the p-type anode layer 25 may be lower than the concentration of the p-type impurity of the p-type base layer 15 of the IGBT region 10 to reduce an amount of holes implanted into the diode region 20 during diode operation. A recovery loss during the diode operation can be reduced by reducing the amount of holes implanted during the diode operation.

A p⁺-type contact layer 24 is provided on the first main surface side of the p-type anode layer 25. The concentration of the p-type impurity of the p⁺-type contact layer 24 may be the same as or different from the concentration of the p-type impurity of the p⁺-type contact layer 14 of the IGBT region 10. The p⁺-type contact layer 24 configures the first main surface of the semiconductor substrate. When the p⁺-type contact layer 24 is a region having a higher concentration of the p-type impurity than the p-type anode layer 25, and when the p⁺-type contact layer 24 and the p-type anode layer 25 are required to be distinguished from each other, they may be referred to individually, and the p⁺-type contact layer 24 and the p-type anode layer 25 may be collectively referred to as a p-type anode layer.

In the diode region 20, an n⁺-type cathode layer 26 is provided on the second main surface side of the n-type buffer layer 3. The n⁺-type cathode layer 26 is provided between the n⁻-type drift layer 1 and the second main surface. The n⁺-type cathode layer 26 is a semiconductor layer containing, for example, the arsenic or the phosphorus as the n-type impurity, and the concentration of the n-type impurity is 1.0×10¹⁶/cm³ to 1.0×10²¹/cm³. As illustrated in FIG. 2, the n⁺-type cathode layer 26 is provided in a part or all of the diode region 20. The n⁺-type cathode layer 26 configures the second main surface of the semiconductor substrate. Although not illustrated, the p-type impurity may be further selectively implanted into the region where the n⁺-type cathode layer 26 is formed as described above, and a p⁺-type cathode layer may be provided using a part of the region where the n⁺-type cathode layer 26 is formed as the p-type semiconductor. The diode in which the n⁺-type cathode layer and the p⁺-type cathode layer are alternately arranged along the second main surface of the semiconductor substrate is referred to as a relaxed field of cathode (RFC) diode.

As illustrated in FIG. 7, the trench that penetrates the p-type anode layer 25 from the first main surface of the semiconductor substrate and reaches the n⁻-type drift layer 1 is formed in the diode region 20 of the semiconductor device 100 or the semiconductor device 101. A diode trench electrode 21a is provided in the trench of the diode region 20 through a diode trench insulating film 21b to configure the diode trench gate 21. The diode trench electrode 21a is opposite to the n⁻-type drift layer 1 through the diode trench insulating film 21b.

As illustrated in FIG. 7, the barrier metal 5 is provided on the diode trench electrode 21a and the p⁺-type contact layer 24. The barrier metal 5 is in ohmic contact with the diode trench electrode 21a and the p⁺-type contact layer 24, and is electrically connected to the diode trench electrode and the p⁺-type contact layer 24. The barrier metal 5 may have the same configuration as the barrier metal 5 in the IGBT region 10. An emitter electrode 6 is provided on the barrier metal 5. The emitter electrode 6 provided in the diode region 20 is formed continuously with the emitter electrode 6 provided in the IGBT region 10. Similarly to the IGBT region 10, the diode trench electrode 21a and the p⁺-type contact layer 24 may be brought into ohmic contact with the emitter electrode 6 without providing the barrier metal 5. Although FIG. 7 illustrates a view in which the interlayer insulating film 4 is not provided on the diode trench electrode 21a of the diode trench gate 21, the interlayer insulating film 4 may be formed on the diode trench electrode 21a of the diode trench gate 21. When the interlayer insulating film 4 is formed on the diode trench electrode 21a of the diode trench gate 21, the emitter electrode 6 and the diode trench electrode 21a may be electrically connected to each other in another section.

The collector electrode 7 is provided on the second main surface side of the n⁺-type cathode layer 26. Similarly to the emitter electrode 6, the collector electrode 7 of the diode region 20 is formed continuously with the collector electrode 7 provided in the IGBT region 10. The collector electrode 7 is in ohmic contact with the n⁺-type cathode layer 26, is electrically connected to the n⁺-type cathode layer 26, and also functions as a cathode electrode.

FIG. 8 is a sectional view illustrating the semiconductor device 100 or the semiconductor device 101 taken along the broken line D-D in FIG. 6 in the arrow direction, and is a sectional view illustrating the diode region 20 in the arrow direction. The sectional view in FIG. 8 is different from the sectional view in the arrow direction indicated by the broken line C-C in FIG. 7 in that the p⁺-type contact layer 24 is not provided between the p-type anode layer 25 and the barrier metal 5 and the p-type anode layer 25 configures the first main surface of the semiconductor substrate. That is, the p⁺-type contact layer 24 in FIG. 7 is selectively provided on the first main surface side of the p-type anode layer 25.

### (5) Boundary Region Between IGBT Region 10 and Diode Region 20

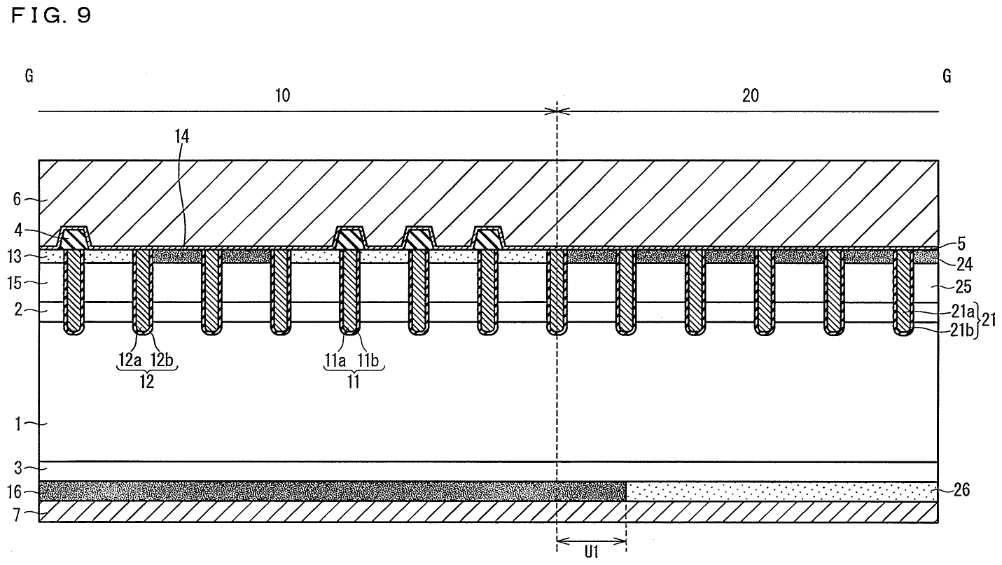

FIG. 9 is a sectional view illustrating a configuration of a boundary between the IGBT region and the diode region of the semiconductor device that is the RC-IGBT. FIG. 9 is a sectional view illustrating the semiconductor device 100 or the semiconductor device 101 in FIG. 1 taken along a broken line G-G in the arrow direction.

As illustrated in FIG. 9, the p-type collector layer 16 provided on the second main surface side of the IGBT region 10 is provided so as to protrude toward the diode region 20 from the boundary between the IGBT region 10 and the diode region 20 by a distance U1. As described above, when the p-type collector layer 16 is provided so as to protrude from the diode region 20, a distance between the n⁺-type cathode layer 26 of the diode region 20 and the active trench gate 11 can be increased, and even when the gate drive voltage is applied to the gate trench electrode 11a during freewheeling diode operation, the current can be prevented from flowing from a channel formed adjacent to the active trench gate 11 of the IGBT region 10 to the n⁺-type cathode layer 26. For example, the distance U1 may be 100 μm. The distance U1 may be zero or a distance smaller than 100 um depending on the application of the semiconductor device 100 or the semiconductor device 101 that is the RC-IGBT.

### (6) General Structure of Termination Region 30

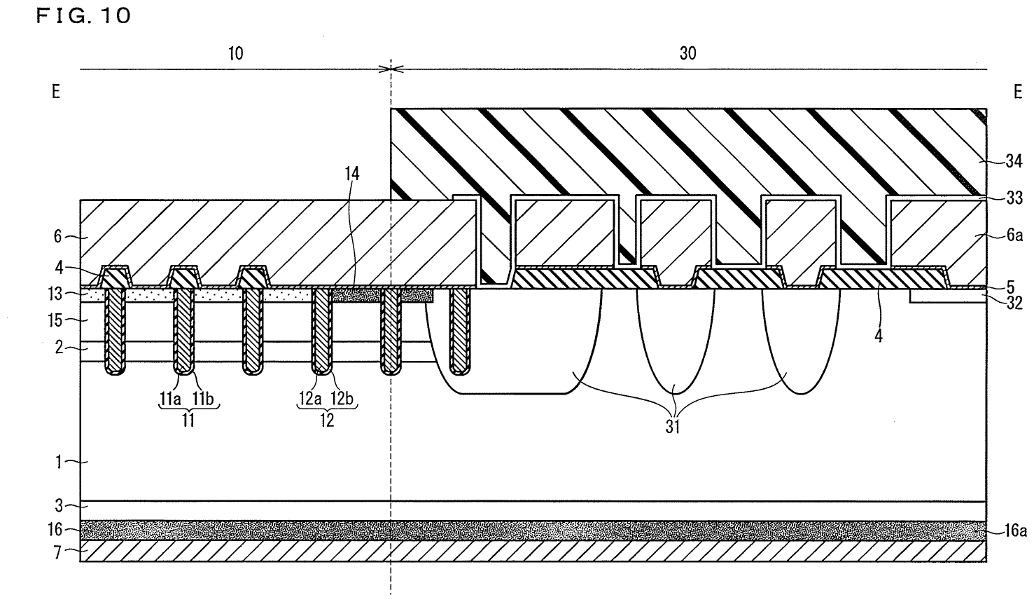

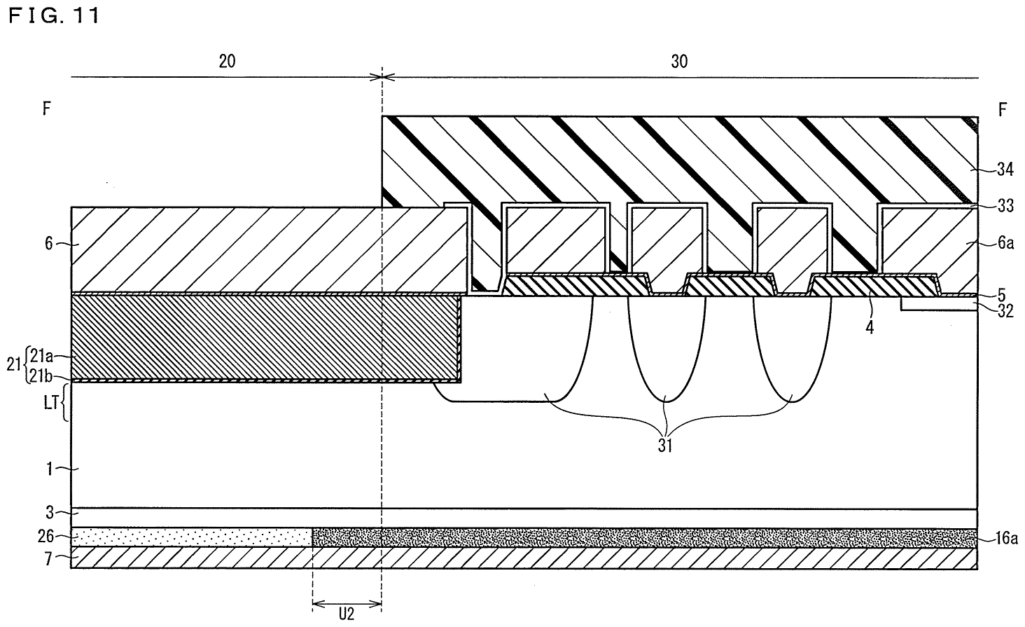

FIGS. 10 and 11 are sectional views illustrating a configuration of the termination region of the semiconductor device that is the RC-IGBT. FIG. 10 is a sectional view taken along a broken line E-E in FIG. 1 or 2 in the arrow direction, and is a sectional view from the IGBT region 10 to the termination region 30. FIG. 11 is a sectional view taken along a broken line F-F in FIG. 1 in the arrow direction, and is a sectional view from the diode region 20 to the termination region 30.

As illustrated in FIGS. 10 and 11, the termination region 30 of the semiconductor device 100 includes the n⁻-type drift layer 1 between the first main surface and the second main surface of the semiconductor substrate. The first main surface and the second main surface of the termination region 30 are flush with the first main surfaces and the second main surfaces in the IGBT region 10 and the diode region 20, respectively. The n⁻-type drift layer 1 in the termination region 30 has the same configuration as the n⁻-type drift layer 1 in the IGBT region 10 and the diode region 20, and is continuously and integrally formed.

A p-type termination well layer 31 is provided on the first main surface side of the n⁻-type drift layer 1, namely, between the first main surface of the semiconductor substrate and the n⁻-type drift layer 1. The p-type termination well layer 31 is a semiconductor layer containing, for example, boron or aluminum as the p-type impurity, and the concentration of the p-type impurity is 1.0×10¹⁴/cm³ to 1.0×10¹⁹/cm³. The p-type termination well layer 31 is provided so as to surround the cell region including the IGBT region 10 and the diode region 20. The p-type termination well layers 31 are provided in a plurality of ring shapes, and the number of the p-type termination well layers 31 to be provided is appropriately selected according to the withstand voltage design of the semiconductor device 100 or the semiconductor device 101. Furthermore, an n⁺-type channel stopper layer 32 is provided on the further outer edge side of the p-type termination well layer 31, and the n⁺-type channel stopper layer 32 surrounds the p-type termination well layer 31.

The p-type termination collector layer 16a is provided between the n⁻-type drift layer 1 and the second main surface of the semiconductor substrate. The p-type termination collector layer 16a is formed integrally and continuously with the p-type collector layer 16 provided in the cell region. Accordingly, the p-type termination collector layer 16a may be referred to as the p-type collector layer 16. Furthermore, in the configuration in which the diode region 20 is provided adjacent to the termination region 30 like the semiconductor device 100 in FIG. 1, as illustrated in FIG. 11, the p-type termination collector layer 16a is provided such that an end portion on the side of the diode region 20 protrudes to the diode region 20 by a distance U2. As described above, when the p-type termination collector layer 16a is provided so as to protrude from the diode region 20, the distance between the n⁺-type cathode layer 26 of the diode region 20 and the p-type termination well layer 31 can be increased, and the p-type termination well layer 31 can be prevented from operating as an anode of a diode. For example, the distance U2 may be 100 μm.

A collector electrode 7 is provided on the second main surface of the semiconductor substrate. The collector electrode 7 is integrally formed continuously from the cell region including the IGBT region 10 and the diode region 20 to the termination region 30. On the other hand, the emitter electrode 6 continuous from the cell region and the termination electrode 6a separated from the emitter electrode 6 are provided on the first main surface of the semiconductor substrate in the termination region 30.

The emitter electrode 6 and the termination electrode 6a are electrically connected through a semi-insulating film 33. For example, the semi-insulating film 33 may be a semi-insulating silicon nitride (sinSiN) film. The termination electrode 6a, the p-type termination well layer 31, and the n⁺-type channel stopper layer 32 are electrically connected through a contact hole formed in the interlayer insulating film 4 provided on the first main surface of the termination region 30. In addition, in the termination region 30, a termination protection film 34 is provided so as to cover the emitter electrode 6, the termination electrode 6a, and the semi-insulating film 33. For example, the termination protection film 34 may be formed of polyimide.

### (7) General Method of Manufacturing RC-IGBT

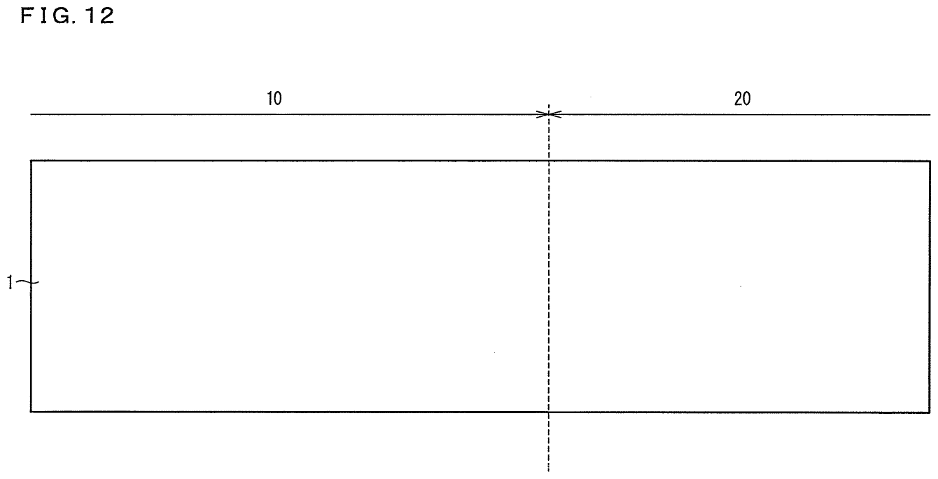

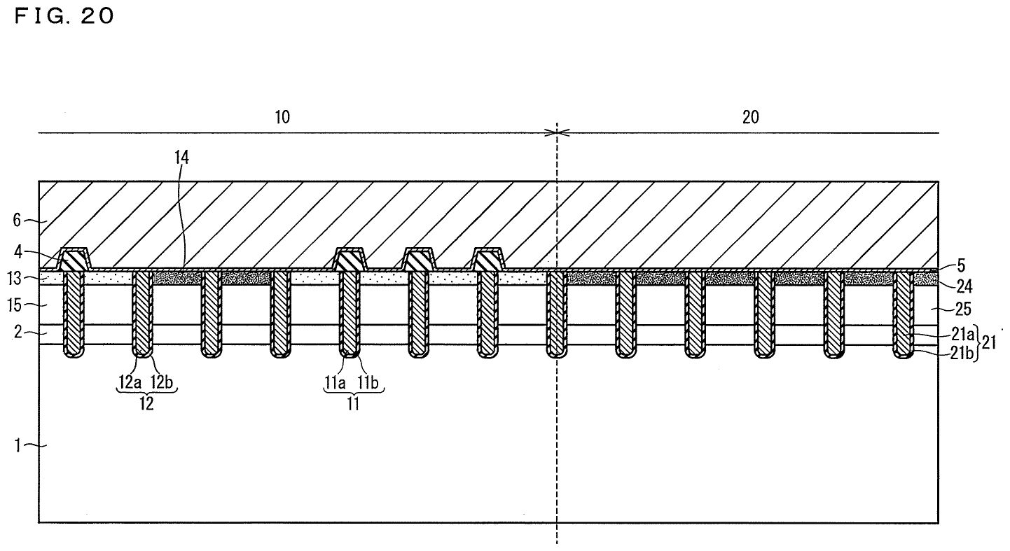

FIGS. 12 to 22 are views illustrating a method of manufacturing the semiconductor device that is the RC-IGBT. FIGS. 12 to 19 are views illustrating a process for forming the front surface side of the semiconductor device 100 or the semiconductor device 101, and FIGS. 20 to 22 are views illustrating a process for forming the back surface side of the semiconductor device 100 or the semiconductor device 101.

First, as illustrated in FIG. 12, the semiconductor substrate configuring the n⁻-type drift layer 1 is prepared. As the semiconductor substrate, for example, what is called a floating zone (FZ) wafer manufactured by an FZ method or what is called a magnetic field applied Czochralski (MCZ) wafer manufactured by an MCZ method may be used, and an n-type wafer containing n-type impurity may be used. The concentration of the n-type impurity contained in the semiconductor substrate is appropriately selected depending on the withstand voltage of the semiconductor device to be manufactured. For example, in the semiconductor device having the withstand voltage of 1200 V, the concentration of the n-type impurity is adjusted such that specific resistance of the n⁻-type drift layer 1 constituting the semiconductor substrate is about 40 to about 120 Ω·cm. As illustrated in FIG. 12, in the process for preparing the semiconductor substrate, the entire semiconductor substrate is the n⁻-type drift layer 1. P-type or n-type impurity ions are implanted from the first main surface side or the second main surface side of the semiconductor substrate, and then diffused into the semiconductor substrate by heat treatment or the like, thereby forming the p-type or n-type semiconductor layer to manufacture the semiconductor device 100 or the semiconductor device 101.

As illustrated in FIG. 12, the semiconductor substrate configuring the n⁻-type drift layer 1 includes a region that becomes the IGBT region 10 and the diode region 20. Although not illustrated, a region that becomes the termination region 30 is provided around the region that becomes the IGBT region 10 and the diode region 20. Hereinafter, a method of manufacturing the configurations of the IGBT region 10 and the diode region 20 of the semiconductor device 100 or the semiconductor device 101 will be mainly described, and the termination region 30 of the semiconductor device 100 or the semiconductor device 101 may be manufactured by a known manufacturing method. For example, when the FLR having the p-type termination well layer 31 as the withstand voltage holding structure is formed in the termination region 30, the FLR may be formed by implanting p-type impurity ions before the IGBT region 10 and the diode region 20 of the semiconductor device 100 or the semiconductor device 101 are processed, or the FLR may be formed by simultaneously implanting p-type impurity ions in implanting the p-type impurity into the IGBT region 10 or the diode region 20 of the semiconductor device 100.

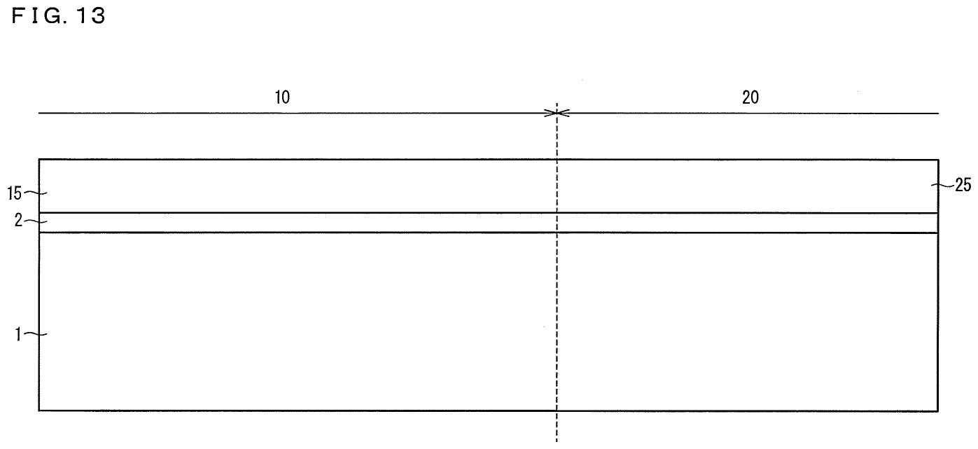

Subsequently, as illustrated in FIG. 13, the n-type impurity such as the phosphorus (P) is implanted from the first main surface side of the semiconductor substrate to form the n-type carrier accumulation layer 2. In addition, the p-type impurity such as boron (B) is implanted from the first main surface side of the semiconductor substrate to form the p-type base layer 15 and the p-type anode layer 25. The n-type carrier accumulation layer 2, the p-type base layer 15 and the p-type anode layer 25 are formed by implanting the impurity ions into the semiconductor substrate and then diffusing the impurity ions by heat treatment. The n-type impurity and the p-type impurity are ion-implanted after mask processing is performed on the first main surface of the semiconductor substrate, so that the n-type impurity and the p-type impurity are selectively formed on the first main surface side of the semiconductor substrate. The n-type carrier accumulation layer 2, the p-type base layer 15, and the p-type anode layer 25 are formed in the IGBT region 10 and the diode region 20, and are connected to the p-type termination well layer 31 at the termination region 30. The mask processing refers to processing for applying a resist on the semiconductor substrate, forming an opening in a predetermined region of the resist using a photolithography technique, and forming a mask on the semiconductor substrate in order to perform the ion implantation or etching on the predetermined region of the semiconductor substrate through the opening.

The p-type base layer 15 and the p-type anode layer 25 may be formed by simultaneous ion implantation of the p-type impurity. In this case, depths and the p-type impurity concentrations of the p-type base layer 15 and the p-type anode layer 25 are the same and have the same configuration. In addition, the depths and the p-type impurity concentrations of the p-type base layer 15 and the p-type anode layer 25 may be made different by separately ion-implanting the p-type impurity into the p-type base layer 15 and the p-type anode layer 25 by the mask processing.

The p-type termination well layer 31 formed in another section may be formed by ion-implanting the p-type impurity simultaneously with the p-type anode layer 25. In this case, the depths and the p-type impurity concentrations of the p-type termination well layer 31 and the p-type anode layer 25 are the same, and can have the same configuration. In addition, the p-type termination well layer 31 and the p-type anode layer 25 can be formed by the simultaneous ion implantation of the p-type impurity, and the p-type impurity of the p-type termination well layer 31 and the p-type anode layer 25 can be set to different concentrations. In this case, one or both of the masks may be used as a mesh-like mask to change the aperture ratio.

In addition, the depths and the p-type impurity concentrations of the p-type termination well layer 31 and the p-type anode layer 25 may be made different by separately ion-implanting the p-type impurity into the p-type termination well layer 31 and the p-type anode layer 25 by the mask processing. The p-type termination well layer 31, the p-type base layer 15, and the p-type anode layer 25 may be formed by the simultaneous ion implantation of the p-type impurity.

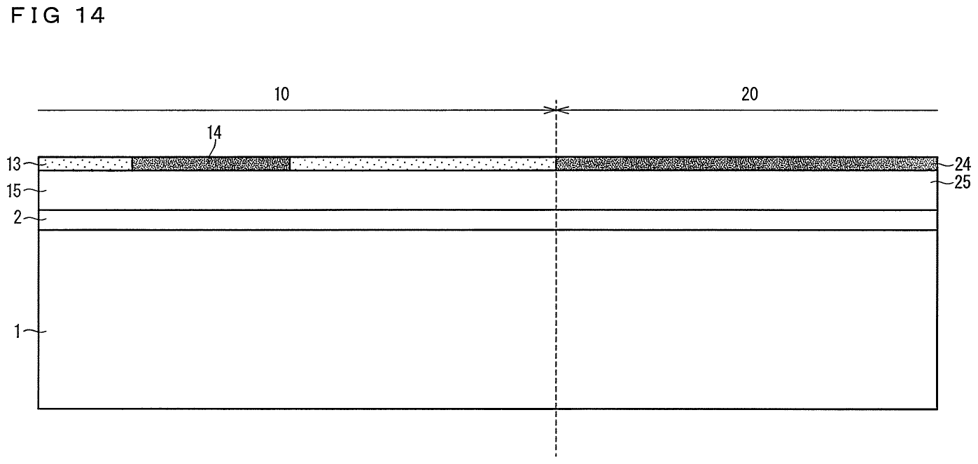

Subsequently, as illustrated in FIG. 14, the n-type impurity is selectively implanted into the IGBT region 10 on the first main surface side of the p-type base layer 15 by the mask processing to form the n⁺-type source layer 13. For example, the implanted n-type impurity is the arsenic (As) or the phosphorus (P). In addition, by the mask processing, the p-type impurity is selectively implanted into the IGBT region 10 on the first main surface side of the p-type base layer 15 to form the p⁺-type contact layer 14, and the p-type impurity is selectively implanted into the diode region 20 on the first main surface side of the p-type anode layer 25 to form the p⁺-type contact layer 24. For example, the implanted p-type impurity is boron (B) or aluminum (Al).

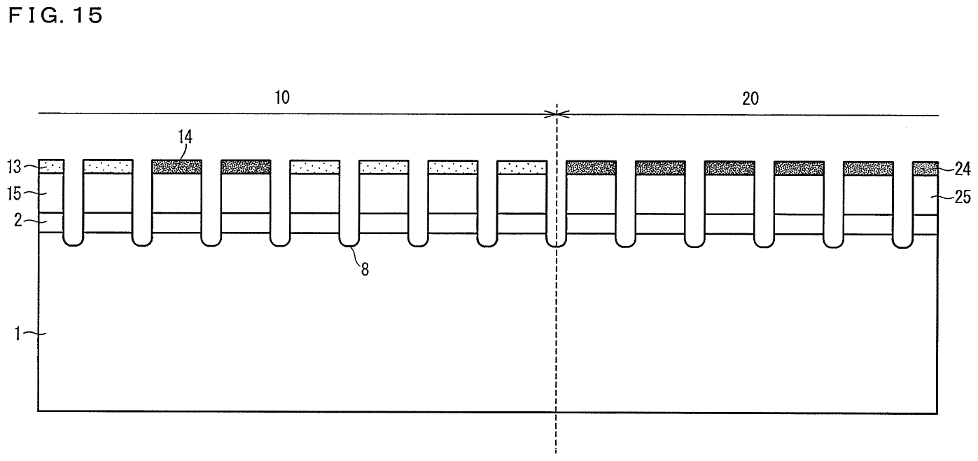

Subsequently, as illustrated in FIG. 15, a trench 8 that penetrates the p-type base layer 15 and the p-type anode layer 25 from the first main surface side of the semiconductor substrate and reaches the n⁻-type drift layer 1 is formed. In the IGBT region 10, the side wall of the trench 8 penetrating the n⁺-type source layer 13 configures a part of the n⁺-type source layer 13. After an oxide film such as SiO₂ is deposited on the semiconductor substrate, an opening is formed in the oxide film at a portion where the trench 8 is formed by the mask processing, and the semiconductor substrate is formed using the oxide film having the opening as a mask, whereby the trench 8 may be formed. In FIG. 15, the IGBT region 10 and the diode region 20 are formed with the same pitch of the trenches 8. However, the IGBT region 10 and the diode region 20 may have different pitches of the trenches 8. The pitch of the trenches 8 can be appropriately changed depending on the mask pattern of the mask processing in planar view.

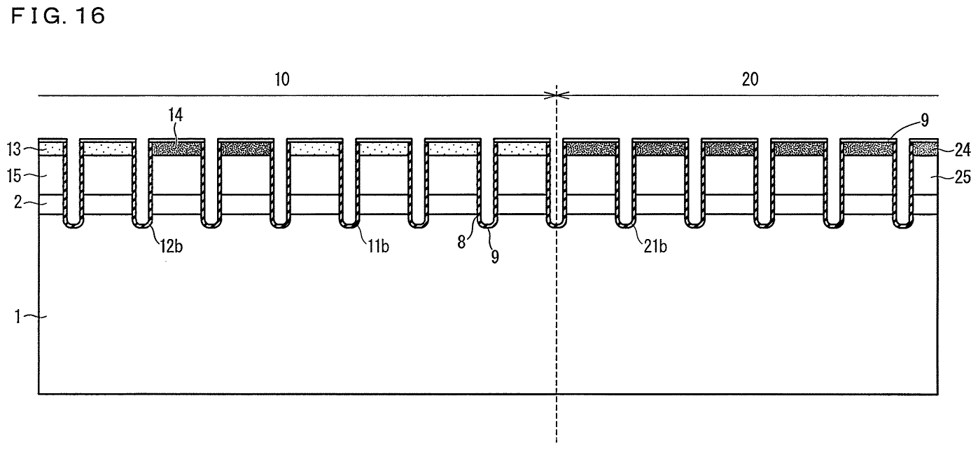

Subsequently, as illustrated in FIG. 16, the semiconductor substrate is heated in an atmosphere containing oxygen to form an oxide film 9 on the inner wall of the trench 8 and the first main surface of the semiconductor substrate. In the oxide film 9 formed on the inner wall of the trench 8, the oxide film 9 formed on the trench 8 of the IGBT region 10 is the gate trench insulating film 11b of the active trench gate 11 and the dummy trench insulating film 12b of the dummy trench gate 12. The oxide film 9 formed in the trench 8 of the diode region 20 is the diode trench insulating film 21b. The oxide film 9 formed on the first main surface of the semiconductor substrate is removed in a later process.

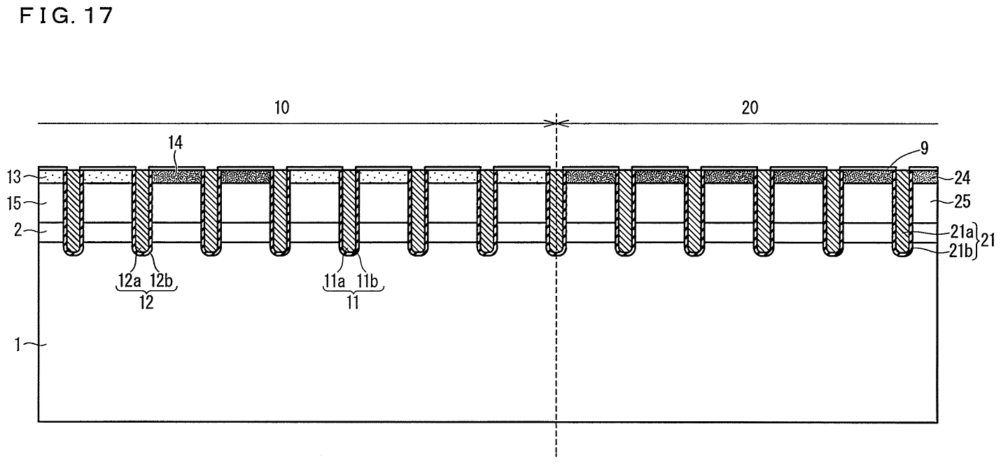

Subsequently, as illustrated in FIG. 17, polysilicon doped with the n-type or p-type impurity by chemical vapor deposition (CVD) or the like is deposited in the trench 8 in which the oxide film 9 is formed on the inner wall, and the gate trench electrode 11a, the dummy trench electrode 12a, and the diode trench electrode 21a are formed.

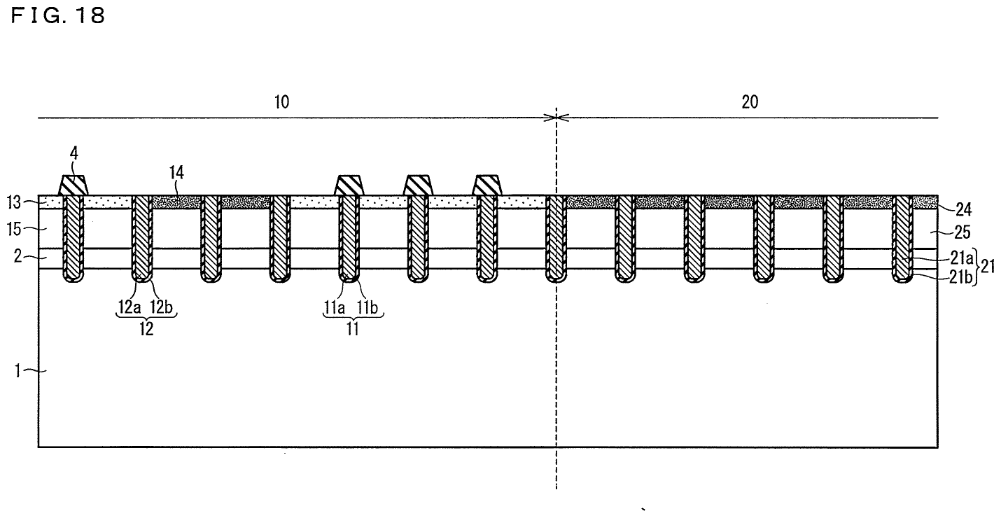

Subsequently, as illustrated in FIG. 18, after the interlayer insulating film 4 is formed on the gate trench electrode 11a of the active trench gate 11 of the IGBT region 10, the oxide film 9 formed on the first main surface of the semiconductor substrate is removed. For example, the interlayer insulating film 4 may be SiO₂. Then, the contact hole is formed in the deposited interlayer insulating film 4 by the mask processing. The contact holes are formed on the n⁺-type source layer 13, the p⁺-type contact layer 14, the p⁺-type contact layer 24, the dummy trench electrode 12a, and the diode trench electrode 21a.

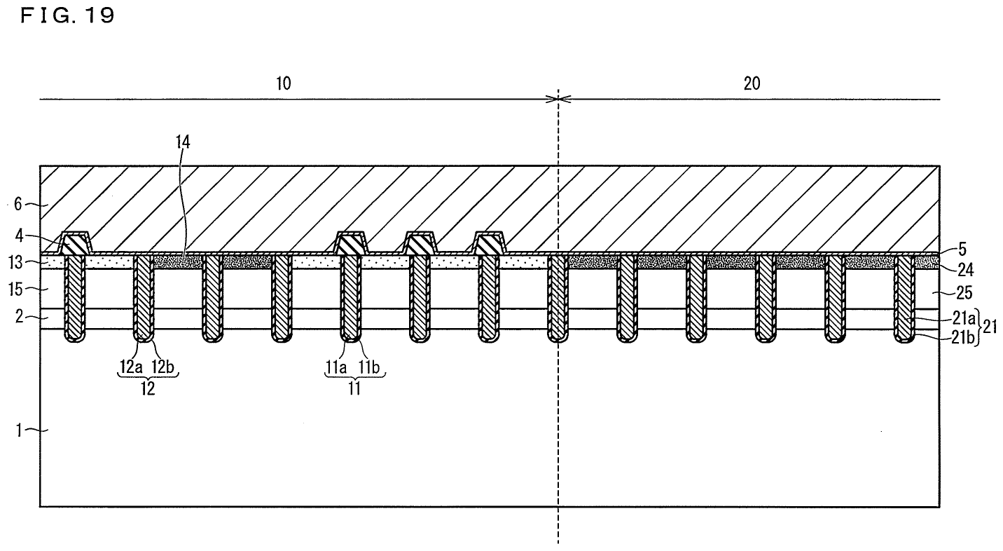

Subsequently, as illustrated in FIG. 19, the barrier metal 5 is formed on the first main surface of the semiconductor substrate and the interlayer insulating film 4, and the emitter electrode 6 is further formed on the barrier metal 5. The barrier metal 5 is formed by depositing titanium nitride by physical vapor deposition (PDV) or CVD.

For example, the emitter electrode 6 may be formed by depositing an aluminum silicon alloy (Al—Si-based alloy) on the barrier metal 5 by PVD such as sputtering or vapor deposition. A nickel alloy (Ni alloy) may be further formed on the formed aluminum silicon alloy by electroless plating or electrolytic plating to form the emitter electrode 6. When the emitter electrode 6 is formed by plating, a thick metal film can be easily formed as the emitter electrode 6, so that a heat capacity of the emitter electrode 6 can be increased to improve heat resistance. When a nickel alloy is further formed by plating after the emitter electrode 6 made of an aluminum silicon alloy is formed by PVD, the plating treatment may be performed in order to form the nickel alloy after the second main surface side of the semiconductor substrate is processed.

Subsequently, as illustrated in FIG. 20, the second main surface side of the semiconductor substrate is ground to thin the semiconductor substrate to a designed predetermined thickness. For example, the thickness of the ground semiconductor substrate is equal to or greater than 80 μm and equal to or smaller than 200 μm.

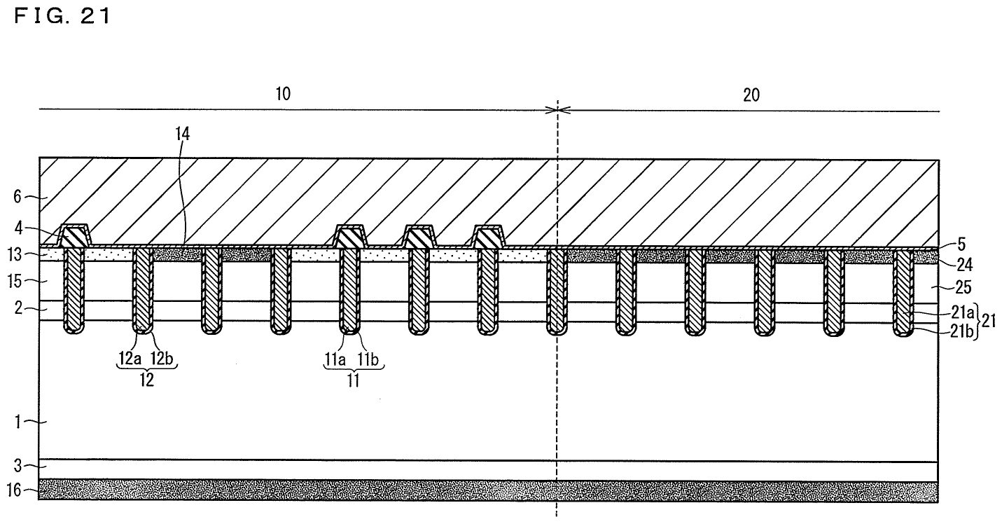

Subsequently, as illustrated in FIG. 21, the n-type impurity is implanted from the second main surface side of the semiconductor substrate to form the n-type buffer layer 3. Furthermore, the p-type impurity is implanted from the second main surface side of the semiconductor substrate to form the p-type collector layer 16. The n-type buffer layer 3 may be formed in the IGBT region 10, the diode region 20, and the termination region 30, or formed only in the IGBT region 10 or the diode region 20.

For example the n-type buffer layer 3 may be formed by implanting a phosphorus (P) ion. In addition, the n-type buffer layer 3 may be formed by implanting a proton (H⁺). Furthermore, both the proton and the phosphorus may be implanted. The proton can be injected from the second main surface of the semiconductor substrate to a deep position with relatively low acceleration energy. In addition, the depth at which the proton is injected can be relatively easily changed by changing the acceleration energy. For this reason, in forming the n-type buffer layer 3 by the proton, when the implantation is performed a plurality of times while the acceleration energy is changed, the n-type buffer layer 3 having the width wider in the thickness direction of the semiconductor substrate than that formed of the phosphorus can be formed.

In addition, the phosphorus can increase an activation rate as the n-type impurity as compared with the proton, so that punch-through of the depletion layer can be more reliably suppressed even in the semiconductor substrate thinned by forming the n-type buffer layer 3 with the phosphorus. In order to further thin the semiconductor substrate, preferably the n-type buffer layer 3 is formed by injecting both the proton and phosphorus, and in this case, the proton is injected at a position deeper from the second main surface than the phosphorus.

For example, the p-type collector layer 16 is formed by implanting boron (B). The p-type collector layer 16 is also formed in the termination region 30, and the p-type collector layer 16 in the termination region 30 becomes the p-type termination collector layer 16a. After the ion implantation from the second main surface side of the semiconductor substrate, the second main surface is irradiated with laser to perform laser annealing, so that implanted boron is activated to form the p-type collector layer 16. At this time, the phosphorus for the n-type buffer layer 3 injected at a relatively shallow position from the second main surface of the semiconductor substrate is also activated at the same time. On the other hand, the proton is activated at a relatively low annealing temperature such as 350° C. to 500° C., so that attention is required to be paid such that the temperature of the entire semiconductor substrate does not become higher than 350° C. to 500° C. except for a process for activating the proton after injecting the proton. The laser annealing can raise the temperature only in the vicinity of the second main surface of the semiconductor substrate, so that the laser annealing can be used for activating the n-type impurity and the p-type impurity even after the proton is implanted.

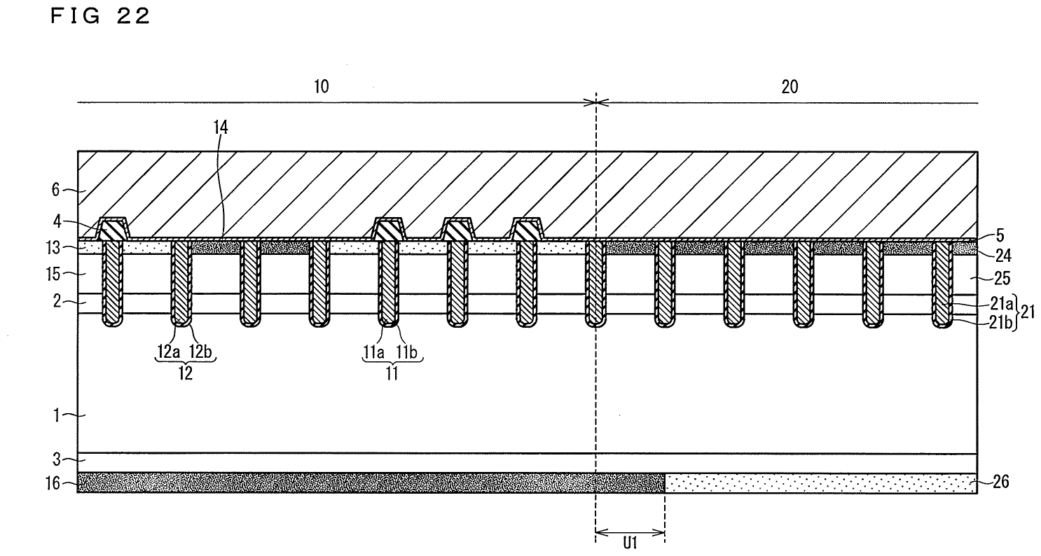

Subsequently, as illustrated in FIG. 22, the n⁺-type cathode layer 26 is formed in the diode region 20. For example, the n⁺-type cathode layer 26 may be formed by implanting the phosphorus (P). As illustrated in FIG. 22, the phosphorus is selectively implanted from the second main surface side by the mask processing such that the boundary between the p-type collector layer 16 and the n⁺-type cathode layer 26 is located at a position at the distance U1 from the boundary between the IGBT region 10 and the diode region 20 toward the side of the diode region 20. An implantation amount of the n-type impurity forming the n⁺-type cathode layer 26 is larger than the implantation amount of the p-type impurity forming the p-type collector layer 16. In FIG. 22, the depths of the p-type collector layer 16 and the n⁺-type cathode layer 26 from the second main surface are the same, but the depth of the n⁺-type cathode layer 26 is equal to or greater than the depth of the p-type collector layer 16. In the region where the n⁺-type cathode layer 26 is formed, the n-type semiconductor is required to be formed by implanting the n-type impurity into the region into which the p-type impurity is implanted, so that the concentration of the implanted p-type impurity is made higher than the concentration of the n-type impurity in the entire region where the n⁺-type cathode layer 26 is formed.

Subsequently, the sectional configuration in FIG. 9 can be obtained by forming the collector electrode 7 on the second main surface of the semiconductor substrate. The collector electrode 7 is formed over the entire surface of the IGBT region 10, the diode region 20, and the termination region 30 on the second main surface. The collector electrode 7 may be formed over the entire second main surface of the n-type wafer as the semiconductor substrate. The collector electrode 7 may be formed by depositing an aluminum silicon alloy (Ai—Si-based alloy), titanium (Ti), or the like by PVD such as sputtering or vapor deposition, or the collector electrode 7 may be formed by laminating a plurality of metals such as an aluminum silicon alloy, titanium, nickel, or gold. Furthermore, a metal film may be further formed on the metal film formed by PVD by electroless plating or electrolytic plating to form the collector electrode 7.

The semiconductor device 100 or the semiconductor device 101 is manufactured by the above processes. A plurality of semiconductor devices 100 or 101 are produced in a matrix on one n-type wafer, so that the semiconductor devices 100 or 101 are completed by being cut into individual semiconductor device 100 or 101 by laser dicing or blade dicing.

### First Preferred Embodiment

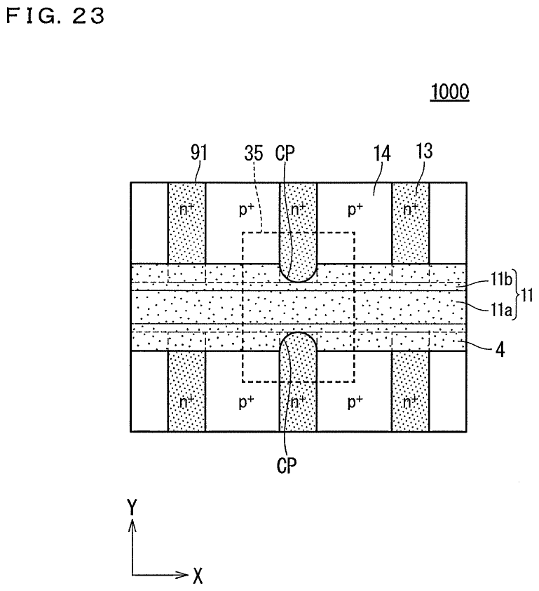

FIG. 23 is a partial plan view illustrating a configuration of an RC-IGBT 1000 according to a first preferred embodiment, and is a plan view in a region 91 surrounded by a broken line in FIG. 3. Therefore, the overall planar structure of the RC-IGBT 1000 is the same as that of the semiconductor device 100 in FIG. 1 or the semiconductor device 101 in FIG. 2.

FIG. 23 illustrates the interlayer insulating film 4 on the active trench gate 11, that is not illustrated in FIG. 3. The interlayer insulating film 4 is provided on the first main surface of the semiconductor substrate so as to overlap with the active trench gate 11.

As illustrated in FIG. 23, the RC-IGBT 1000 has a structure in which the width of the interlayer insulating film 4 on the active trench gate 11 is partially narrowed. Hereinafter, the structure is referred to as a narrow width portion 35. In the narrow width portion 35, a recess CP is partially provided on each of two side surfaces of the interlayer insulating film 4 in the width direction that is a Y-direction intersecting an X-direction that is the extending direction of the active trench gate 11 in planar view. In the portion where the recess CP is provided, the width of the interlayer insulating film 4 is narrowed and is approximately the same as the width of the active trench gate 11. For this reason, when the emitter electrode 6 (FIG. 4) is provided on the first main surface of the semiconductor substrate, the distance between the gate trench electrode 11a and the emitter electrode 6 is shorter in the narrow width portion 35 than in a portion where the width of the interlayer insulating film 4 is a normal width. This may increase the concentration of the electric field and the leakage current.

At this point, in the case where abnormality is generated such as the case where the film thickness of the gate trench insulating film 11b decreases during manufacturing and the case where the mask during patterning of the interlayer insulating film 4 deviates and the interlayer insulating film 4 deviates in the width direction of the active trench gate 11, the distance between the gate trench electrode 11a and the emitter electrode 6 may be further shortened, which is a point where breakdown is easily generated when the voltage is applied between the gate and the emitter. When the voltage is applied between the gate and the emitter at such a point, the portion of the narrow width portion 35 undergoes dielectric breakdown, so that an effect equivalent to screening of dielectric breakdown resistance of the gate, namely, a screening effect can be imparted.

In addition, in the RC-IGBT 1000, although the narrow width portion 35 is provided in the interlayer insulating film 4, the width of the interlayer insulating film 4 other than the portion provided with the narrow width portion 35 is not increased, so that a contact region with the emitter electrode 6 is not narrowed. For this reason, the current path in the state where the IGBT is turned on is not narrowed, the on-resistance is not increased, and the loss of the transistor is not increased.

As described with reference to FIG. 18, the narrow width portion 35 can be provided in the interlayer insulating film 4 by simultaneously performing patterning using the same mask when a contact hole is formed in the interlayer insulating film 4 by the mask processing. However, after the contact hole is formed, only the recess CP can be formed using another mask. The recess CP desirably has a size that does not reach at least above the gate trench electrode 11a.

FIG. 23 illustrates an example in which the narrow width portion 35 is provided at one position of the interlayer insulating film 4 on one gate trench electrode 11a, but the present invention is not limited thereto. The narrow width portion 35 can also be provided on the interlayer insulating film 4 on a plurality of gate trench electrodes 11a, and the number of disposed narrow width portions 35 is not limited.

Even when the narrow width portion 35 is provided, it is needless to say that the RC-IGBT1000 functions normally under a normal use condition and a product life is also guaranteed.

### Second Preferred Embodiment

### Device Configuration

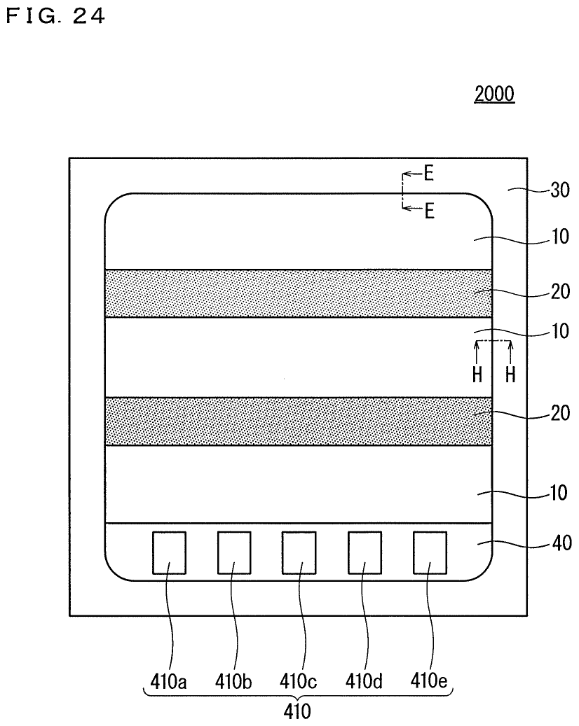

FIG. 24 is an overall plan view illustrating a configuration of an RC-IGBT 2000 according to a second preferred embodiment, and is the same as the semiconductor device 100 in FIG. 1 in appearance. The external appearance can be the same as that of the semiconductor device 101 in FIG. 2, and there is no characteristic in the external appearance.

The RC-IGBT 2000 of the second preferred embodiment is characterized in that a step is provided between the IGBT region 10 and the termination region 30, and that the interlayer insulating film above the step is recessed.

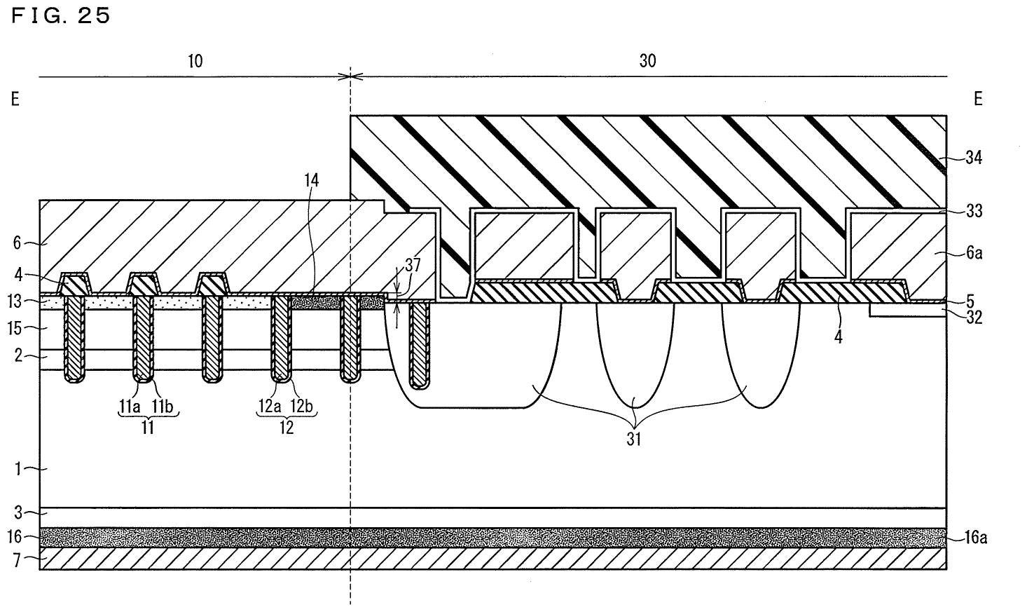

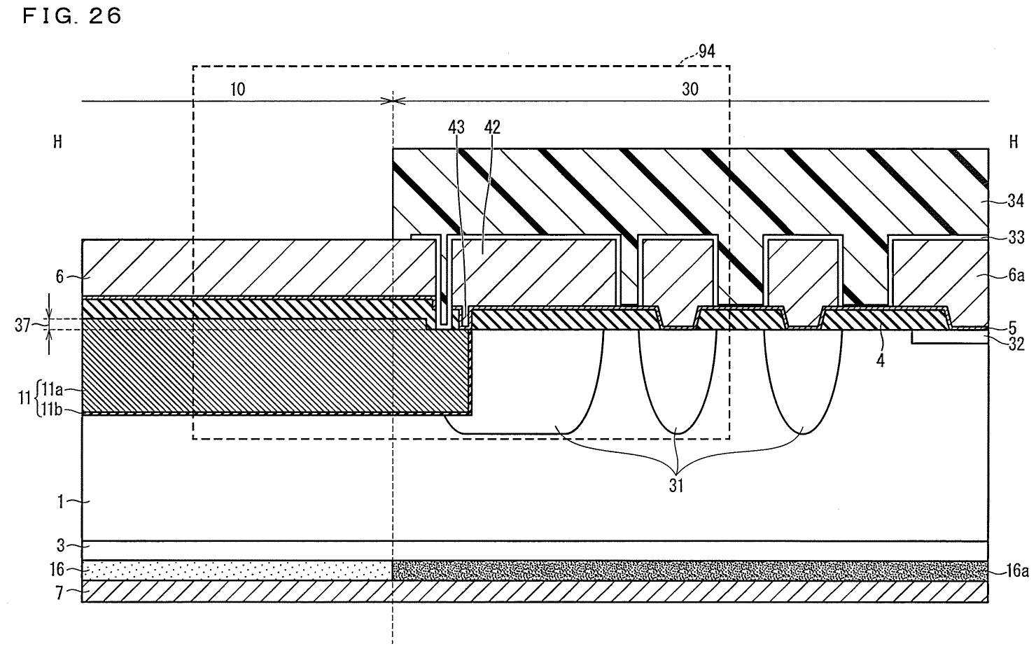

FIG. 25 is a sectional view taken along a broken line E-E in FIG. 24 in the arrow direction, is a sectional view from the IGBT region 10 to the termination region 30, and is a sectional view in a direction intersecting the extending direction of the active trench gate 11. FIG. 26 is a sectional view taken along a broken line H-H in FIG. 24 in the arrow direction, is a sectional view from the IGBT region 10 to the termination region 30, and is a sectional view in the extending direction of the active trench gate 11.

FIGS. 25 and 26 are basically the same as the sectional views in FIGS. 10 and 11, but a step 37 having a height difference (height) of about 50 nm is formed by retracting the first main surface of the semiconductor substrate on the side of the termination region 30 from the boundary between the IGBT region 10 and the termination region 30 toward the side of the collector electrode 7.

Due to the presence of the step 37, the interlayer insulating film 4 on the upper portion of the step 37 is recessed as illustrated in FIG. 26.

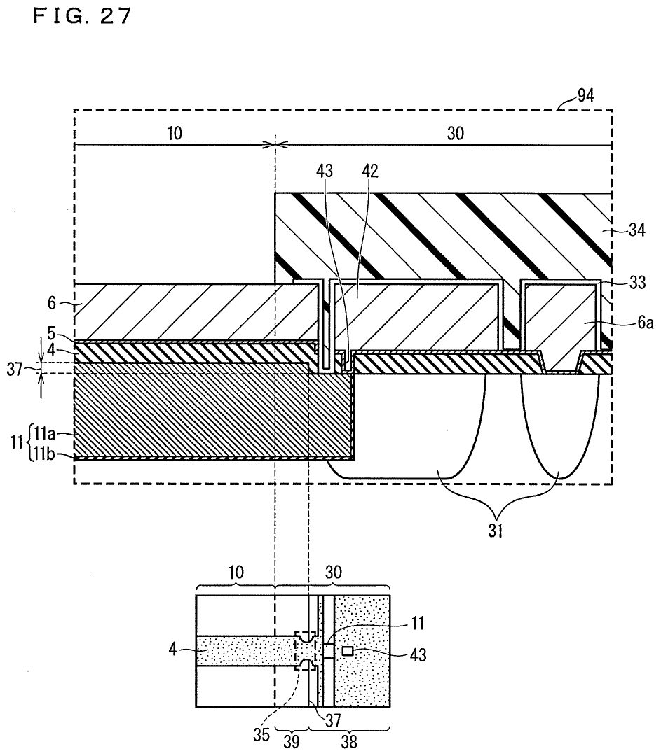

FIG. 27 illustrates a partial sectional view illustrating a region 94 surrounded by a broken line in FIG. 26 and a partial plan view including the narrow width portion 35. An upper view of FIG. 27 is a partially enlarged view, and a lower view is a partial plan view and illustrates a configuration below the interlayer insulating film 4 for convenience. As illustrated in the upper view of FIG. 27, the step 37 of the semiconductor substrate exists on the side of the termination region 30 from the boundary between the IGBT region 10 and the termination region 30, namely, at a position corresponding to the end of the p-type termination well layer 31 closest to the IGBT region 10, and the interlayer insulating film 4 on the step 37 is recessed. When the interlayer insulating film 4 is recessed, the narrow width portion 35 is formed in a recessed portion when the interlayer insulating film 4 is patterned on the active trench gate 11 as illustrated in the lower view of FIG. 27. As a result, the screening effect can be imparted similarly to the RC-IGBT 1000 of the first preferred embodiment.

An active region 38 and an inactive region 39 in termination region 30 are illustrated in FIG. 27. The active region 38 is a region where the p-type termination well layer 31 is formed, and the inactive region 39 is a region from the boundary between the IGBT region 10 and the termination region 30 to the step 37.

At this point, in the active region 38, as illustrated in the upper view of FIG. 27, a gate wiring 42 is provided adjacent to the inactive region 39, and the gate wiring 42 is connected to the gate trench electrode 11a through the gate pull-up portion 43 penetrating the interlayer insulating film 4. The upper view of FIG. 27 discloses a configuration in which the gate wiring 42 is connected to the gate trench electrode 11a through the barrier metal 5, but the barrier metal 5 is arbitrarily disposed.

The gate wiring 42 is electrically connected to a gate pad 410c (FIG. 24) and electrically separated from the emitter electrode 6. As illustrated in the upper view of FIG. 27, the termination protection film 34 is disposed between the gate wiring 42 and the emitter electrode 6 to insulate the gate wiring 42 and the emitter electrode 6 from each other.

### Manufacturing Method

Subsequently, a method of manufacturing the RC-IGBT 2000 will be described with reference to FIGS. 28 to 35 that are sectional views sequentially illustrating manufacturing processes. FIGS. 28 to 35 are views corresponding to the sectional view in FIG. 26.

As illustrated in FIG. 28, a resist mask RM1 including an opening OP in a region where the p-type termination well layer 31 is formed, and the p-type impurity is ion-implanted using the resist mask RM1 as an ion implantation mask to form the p-type termination well layer 31. The p-type termination well layer 31 is a semiconductor layer containing, for example, boron or aluminum as the p-type impurity, and the concentration of the p-type impurity is 1.0×10¹⁴/cm³ to 1.0×10¹⁹/cm³.

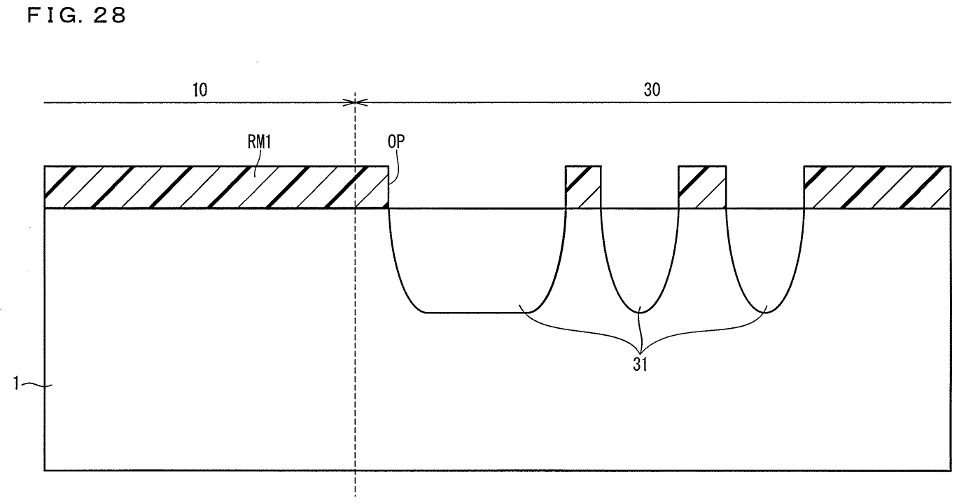

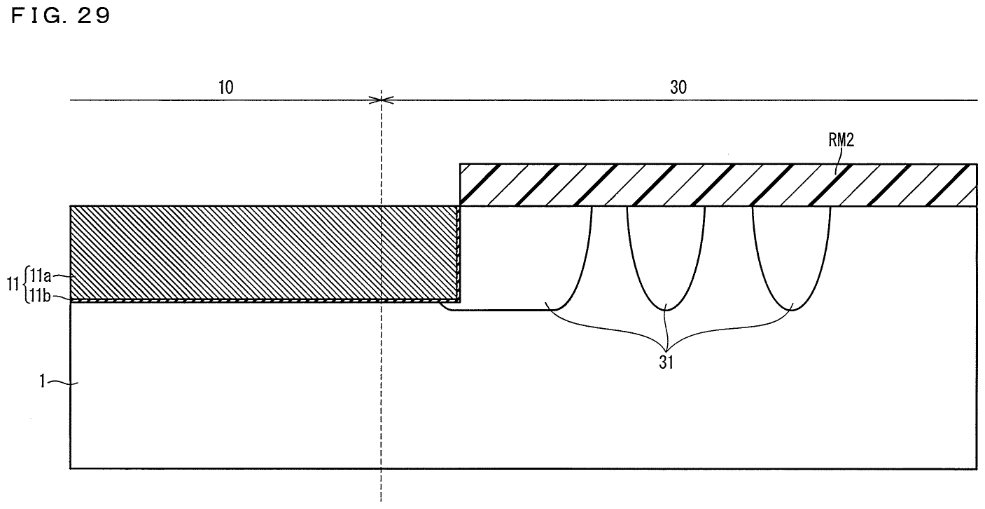

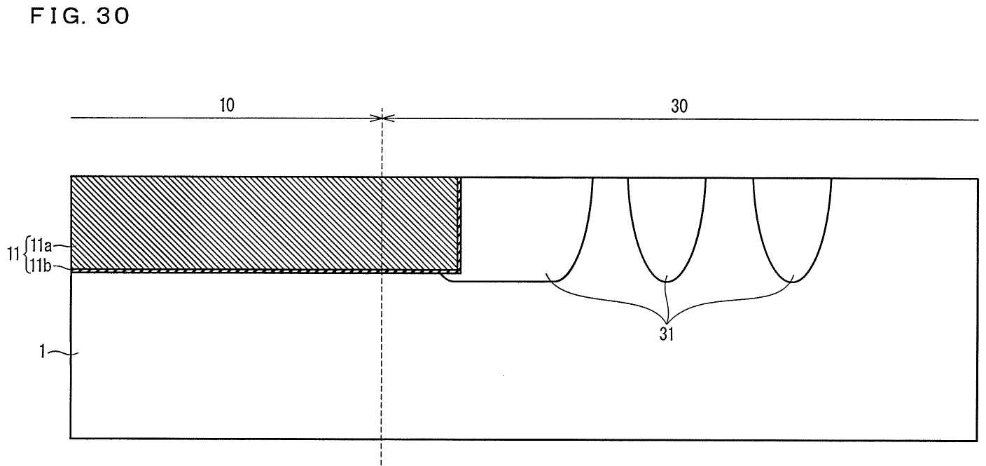

Subsequently, in the process of FIG. 29, the region where the p-type termination well layer 31 is formed is covered with a resist mask RM2, and polysilicon doped with the n-type or p-type impurity by CVD or the like is deposited in the trench in which the gate trench insulating film 11b is formed on the inner wall to form the gate trench electrode 11a, thereby forming the active trench gate 11. FIG. 29 is a view corresponding to the process in FIG. 17, and FIGS. 29 to 35 illustrate manufacturing processes after the process in FIG. 17. As illustrated in FIG. 29, the polysilicon doped with the n-type or p-type impurity by CVD or the like is deposited in the trench in which the gate trench insulating film 11b is formed on the inner wall to form the gate trench electrode 11a, thereby forming the active trench gate 11. Thereafter, the resist mask RM2 is removed as illustrated in FIG. 30.

Subsequently, in the process of FIG. 31, and a resist mask RM21 is formed on the first main surface of the semiconductor substrate except for the region where the first main surface of the semiconductor substrate is retracted to provide the step 37. The region where the step 37 is provided is an opening OP1.

Thereafter, the first main surface of the semiconductor substrate is etched using the resist mask RM21 as an etching mask, and the first main surface of the semiconductor substrate that is not covered with the resist mask RM21 is removed by about 50 nm to form the step 37.

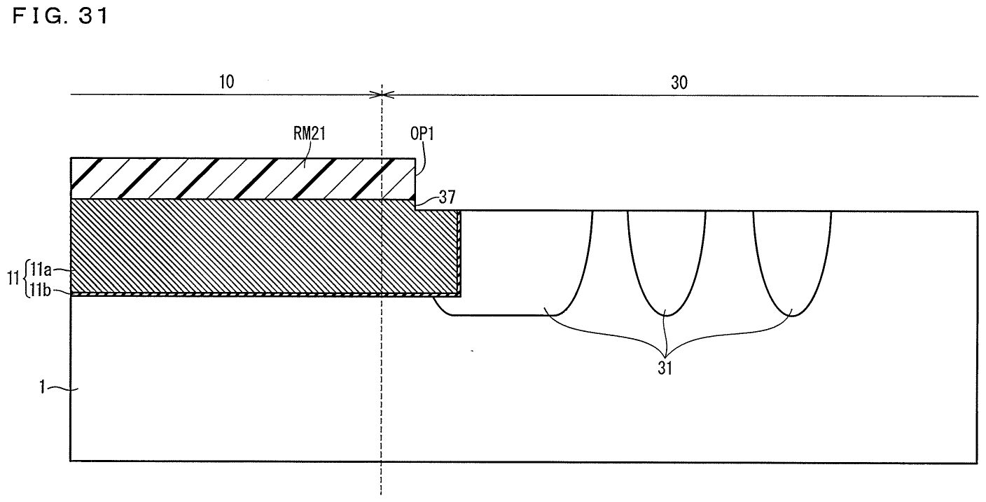

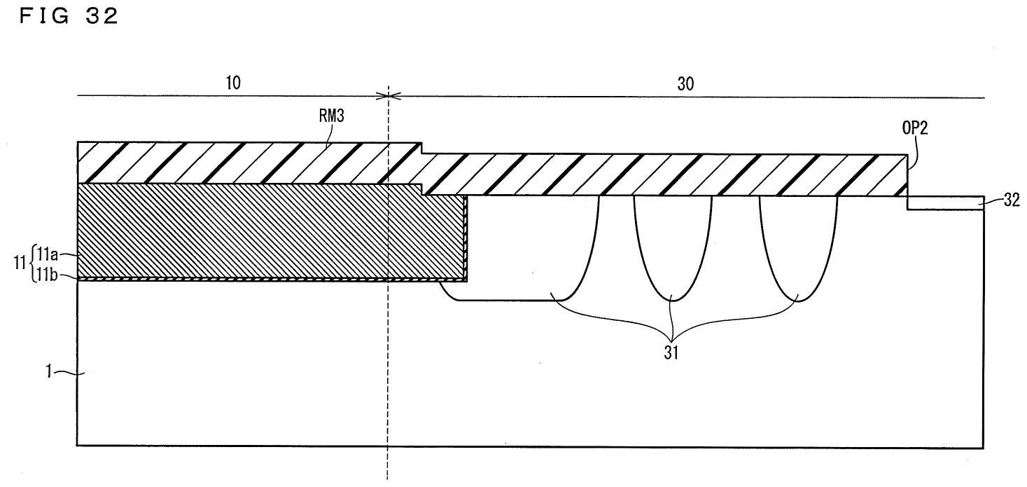

Subsequently, in the process of FIG. 32, a resist mask RM3 including an opening OP2 in the region where the n⁺-type channel stopper layer 32 is formed, and the n-type impurity is ion-implanted using the resist mask RM3 as the ion implantation mask to form the n⁺-type channel stopper layer 32.

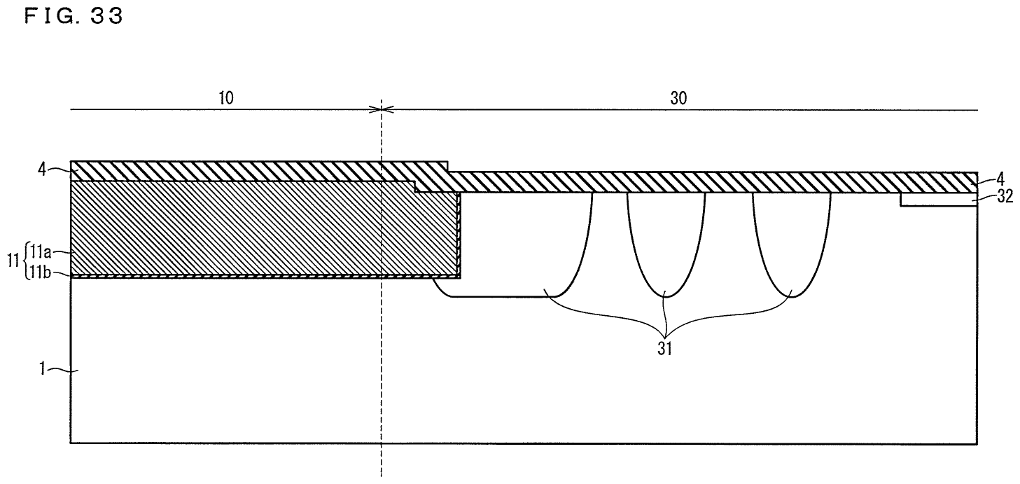

Subsequently, in the process of FIG. 33, the interlayer insulating film 4 is formed entirely on the first main surface of the semiconductor substrate.

In the process of FIG. 34, a resist mask RM4 is formed. In the resist mask RM4, an opening where the interlayer insulating film 4 is patterned on the active trench gate 11 and a portion where the gate pull-up portion 43 is formed in the interlayer insulating film 4 becomes an opening OP3, and a portion where the contact hole is formed becomes an opening OP4.

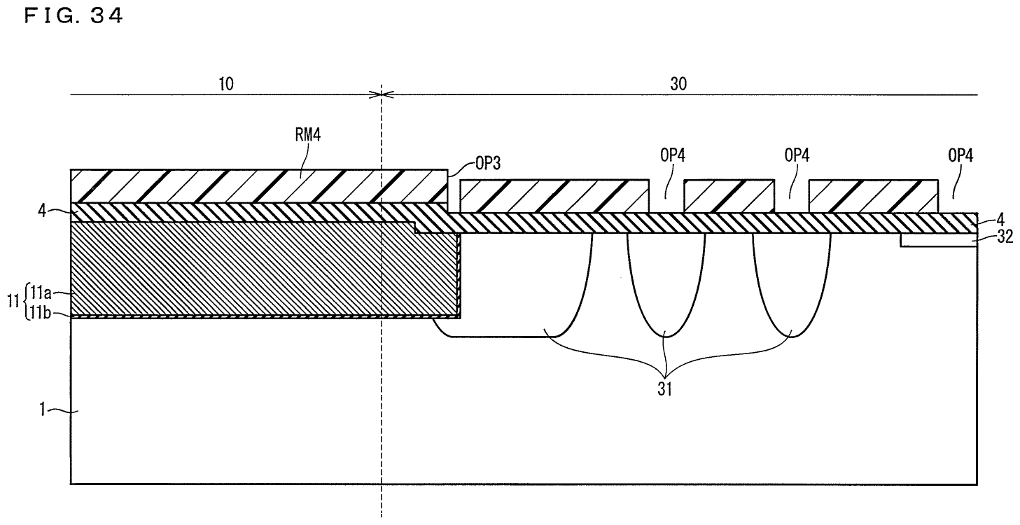

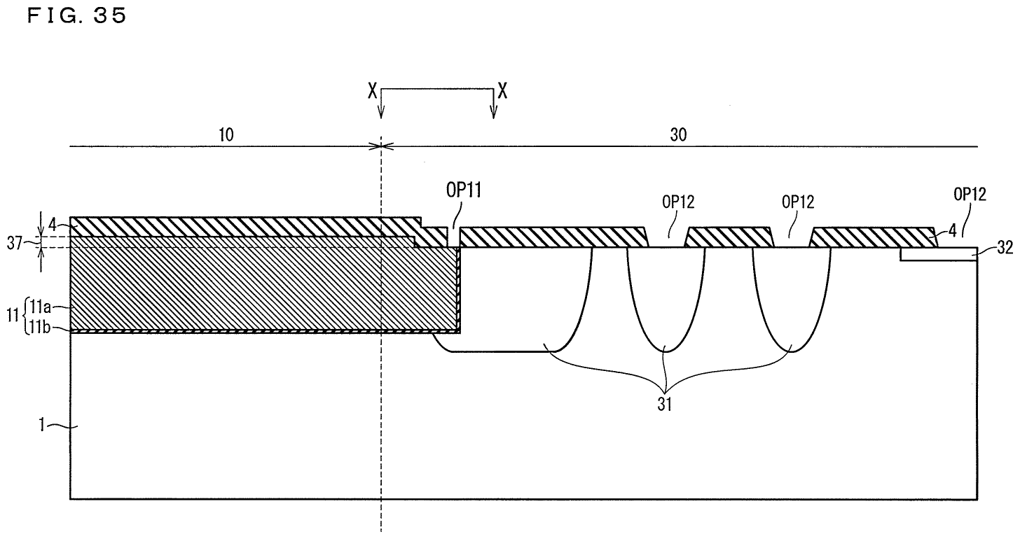

Subsequently, in the process of FIG. 35, the interlayer insulating film 4 is patterned using the resist mask RM4 as the etching mask, the interlayer insulating film 4 covers the active trench gate 11, an opening OP11 is formed in the gate pull-up portion 43, and an opening OP12 is formed in a portion where the contact hole is made.

When the resist mask RM4 is patterned, in the resist mask RM4 on the step 37, the shape of the resist mask RM4 changes due to a shift in focus during exposure, and a narrow width portion 35 in which the width of the interlayer insulating film 4 is narrowed is formed.

In FIG. 35, an arrow-direction plan view taken along a line X-X in the vicinity of the boundary between the IGBT region 10 and the termination region 30 corresponds to the lower view of FIG. 27.

As described above, when the step 37 is provided at the position where the narrow width portion 35 is to be formed, the narrow width portion 35 is formed using an existing resist mask patterning the interlayer insulating film 4, so that the manufacturing process can be simplified.

### Third Preferred Embodiment

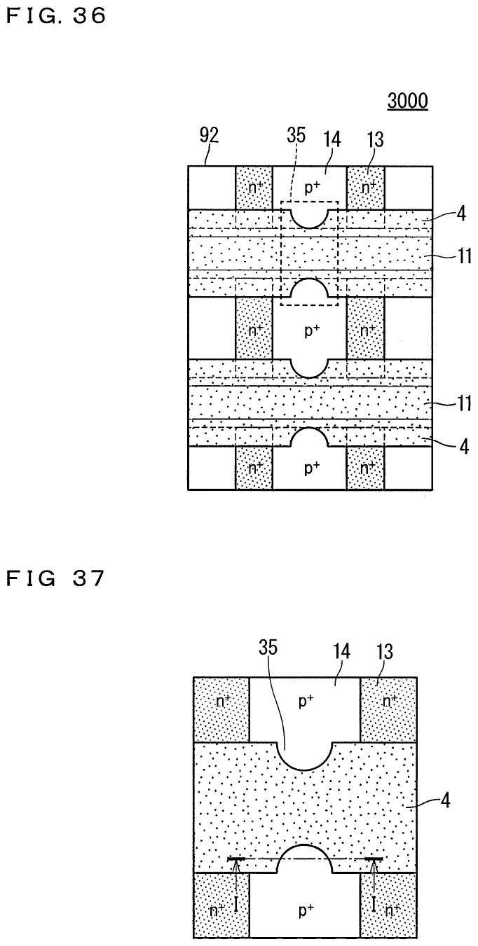

FIG. 36 is a partial plan view illustrating a configuration of an RC-IGBT 3000 according to a third preferred embodiment, and is a plan view in a region 92 surrounded by the broken line in FIG. 3. For this reason, the overall planar structure of the RC-IGBT 3000 is the same as that of the semiconductor device 100 in FIG. 1 or the semiconductor device 101 in FIG. 2.

FIG. 36 illustrates the interlayer insulating film 4 on the active trench gate 11, the interlayer insulating film 4 been not illustrated in FIG. 3. The interlayer insulating film 4 is provided on the first main surface of the semiconductor substrate so as to overlap with the active trench gate 11.

As illustrated in FIG. 36, in the RC-IGBT 3000, the narrow width portion 35 of the interlayer insulating film 4 is formed in a portion where the p⁺-type contact layer 14 adjacent to the n⁺-type source layer 13 is provided.

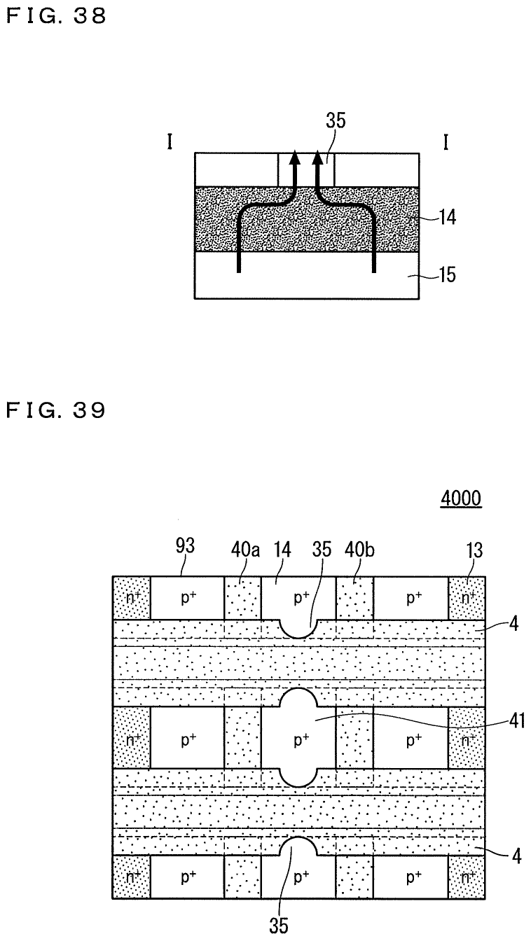

FIG. 37 is an enlarged view of the narrow width portion 35, and FIG. 38 is a sectional view taken along a broken line I-I in FIG. 37 in the arrow direction. In a test in which a large current flows, such as a RBSOA and a short circuit test, a hole existing inside is discharged from the p⁺-type contact layer 14 when the IGBT interrupts the current. At this point, in the narrow width portion 35, the current concentrates in a path indicated by an arrow in FIG. 38. Consequently, a large amount of heat is generated as compared with other portions, and a narrow width effect such as easy destruction is brought about.

In the RBSOA and the short circuit test, a measurement condition such as an increase in the amount of flowing current are gradually tightened and measurement is performed until breakdown is generated. For this reason, the measurement condition under which the IGBT to be tested breaks can be controlled due to the narrow width effect by providing the narrow width portion 35, and a variation in the breakdown resistance can be reduced. At this point, the variation in the breakdown resistance means that even IGBTs manufactured under similar process conditions have variations in conditions under which the IGBTs can operate in a non-destructive manner in a fracture test such as the RBSOA and the short circuit test.

FIG. 36 illustrates an example in which the narrow width portion 35 is provided in the interlayer insulating film 4 on the two gate trench electrodes 11a, but the present invention is not limited thereto. The narrow width portion 35 can also be provided only in the interlayer insulating film 4 on one gate trench electrode 11a, and the number of disposed narrow width portions 35 is not limited.

Even in the case where the narrow width portion 35 is provided, the RC-IGBT 3000 functions normally under the normal use condition, and the product life is also guaranteed. However, the provision of the narrow width portion 35 imparts the screening effect on the dielectric breakdown resistance of the gate similarly to the first preferred embodiment.

### Fourth Preferred Embodiment

FIG. 39 is a partial plan view illustrating a configuration of the RC-IGBT 4000 according to a fourth preferred embodiment, and is a plan view in a region 93 surrounded by the broken line in FIG. 3. For this reason, the overall planar structure of the RC-IGBT 4000 is the same as that of the semiconductor device 100 in FIG. 1 or the semiconductor device 101 in FIG. 2.

In FIG. 39, similarly to the RC-IGBT 3000 in FIG. 36, the narrow width portion 35 of the interlayer insulating film 4 is formed in the portion where the p⁺-type contact layer 14 adjacent to the n⁺-type source layer 13 is provided, and crossing-direction interlayer insulating films 40a and 40b are also formed on the n⁺-type source layer 13 adjacent to the p⁺-type contact layer 14, and the interlayer insulating film 4 in which the narrow width portion 35 is formed and the region 41 surrounded by the crossing-direction interlayer insulating films 40a and 40b are formed.

In a test in which a large current flows, such as a RBSOA and a short circuit test, a hole existing inside is discharged from the p⁺-type contact layer 14 when the IGBT interrupts the current. At this point, the current flows from a periphery of the region 41 to the inside of the region 41 by providing the region 41, so that the current is more concentrated on the narrow width portion 35 as compared with the case of the third preferred embodiment. Consequently, the narrow width effect is further enhanced, and the variation in the breakdown resistance can be further reduced.

Even in the case where the region 41 including the narrow width portion 35 is provided, the RC-IGBT 4000 functions normally under the normal use condition, and the product life is also guaranteed. However, the provision of the region 41 including the narrow width portion 35 imparts the screening effect on the dielectric breakdown resistance of the gate similarly to the first preferred embodiment.

### Fifth Preferred Embodiment

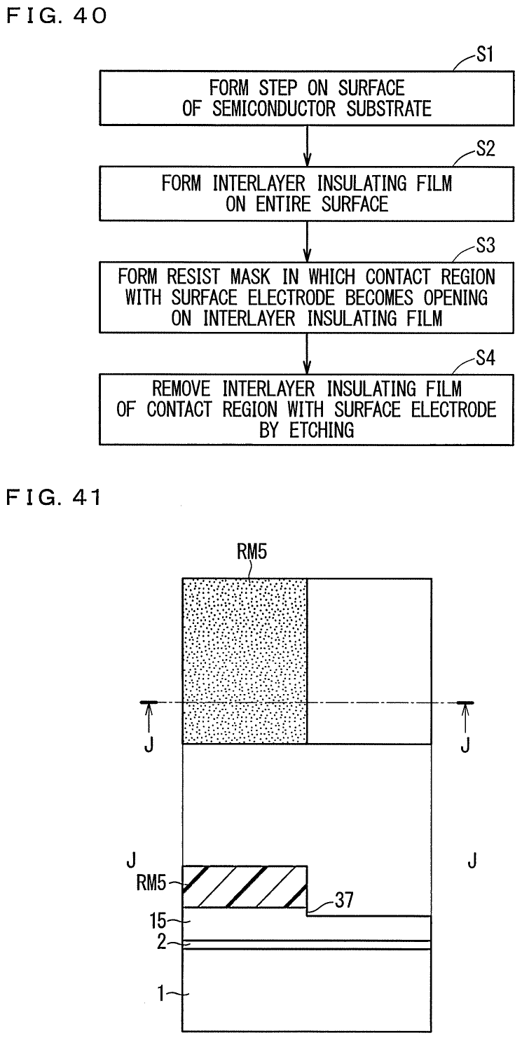

A method of manufacturing the RC-IGBT according to the first, third, and fourth embodiments will be described below. FIG. 40 is a flowchart illustrating a method of manufacturing the RC-IGBT, and FIGS. 41 to 45 are views illustrating a manufacturing process. In the following description, a method of forming the narrow width portion by providing the step on the first main surface of the semiconductor substrate will be described.

As illustrated in FIG. 40, first, the step is formed on the first main surface that is the surface of the semiconductor substrate (step S1). FIG. 41 schematically illustrates this process, the upper view of FIG. 41 illustrates a plan view, and the lower view illustrates a sectional view in the arrow direction taken along a broken line J-J in the upper view.

As illustrated in FIG. 41, a resist mask RM5 forming the step 37 is formed on the first main surface of the semiconductor substrate on which the n-type carrier accumulation layer 2 and the p-type base layer 15 are formed, and the first main surface of the semiconductor substrate is removed by about 50 nm by dry etching or wet etching using the resist mask RM5 as the etching mask to form the step 37. In this case, the step 37 is provided so as to intersect the extending direction of the active trench gate 11.

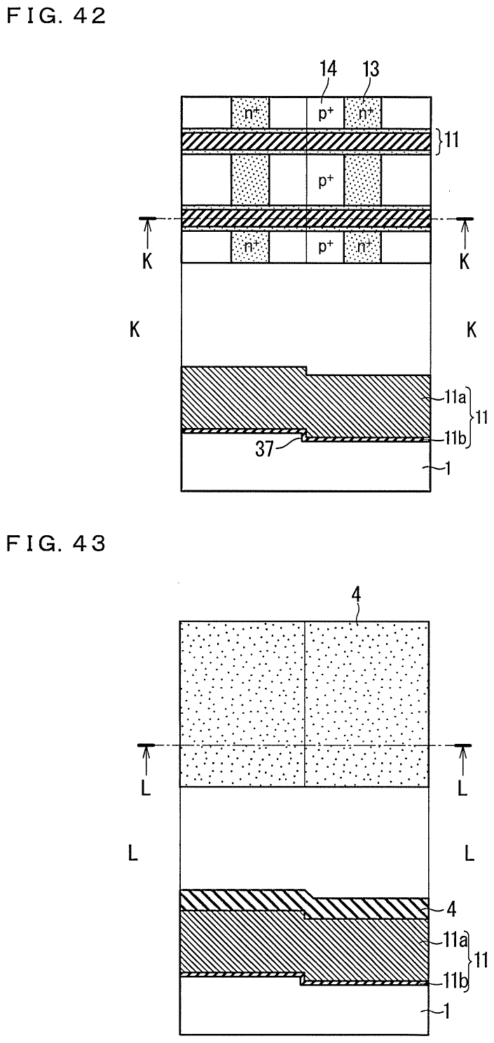

Thereafter, the n⁺-type source layer 13, the p⁺-type contact layer 14, the gate trench insulating film 11b, and the gate trench electrode 11a are formed in the semiconductor substrate as illustrated in FIG. 42 through the processes described with reference to FIGS. 14 to 17. In FIG. 42, the upper view illustrates a plan view, and the lower view illustrates a sectional view in the arrow direction along a broken line K-K in the upper view. In the example of FIG. 42, the step 37 is formed so as to cross between the adjacent n⁺-type source layers 13, but the position where the step 37 is provided is not limited thereto.

Returning to the description of FIG. 40, the interlayer insulating film 4 is formed on the entire first main surface of the semiconductor substrate (step S2). For example, the interlayer insulating film 4 can be SiO₂ formed by CVD. FIG. 43 schematically illustrates this process, an upper view of FIG. 43 illustrates a plan view, and a lower view illustrates a sectional view in the arrow direction along a broken line L-L in the upper view.

As illustrated in the lower view of FIG. 43, the interlayer insulating film 4 on the upper portion of the step 37 is recessed by providing the step 37 on the semiconductor substrate.

Returning to the description of FIG. 40, a resist mask RM6 in which the upper portions of the n⁺-type source layer 13 and the p⁺-type contact layer 14 serving as the contact regions with the emitter electrode serving as the surface electrode become an opening OP5 is formed on the interlayer insulating film 4 (step S3).

FIG. 44 schematically illustrates this process, an upper view of FIG. 44 illustrates a plan view, and a lower view illustrates a sectional view in the arrow direction along a broken line M-M in the upper view.

As illustrated in the upper view of FIG. 44, because the interlayer insulating film 4 on the upper portion of the step 37 is recessed, the resist mask RM6 on the interlayer insulating film 4 is shifted in focus during the exposure, the shape of the resist mask RM6 is changed between the step 37 and other portions, and the width of the resist mask RM6 is partially narrowed.

Returning to the description of FIG. 40, the resist mask RM6 is used as the etching mask, and the interlayer insulating film 4 in the contact region with the emitter electrode that is the surface electrode is removed by etching (step S4).

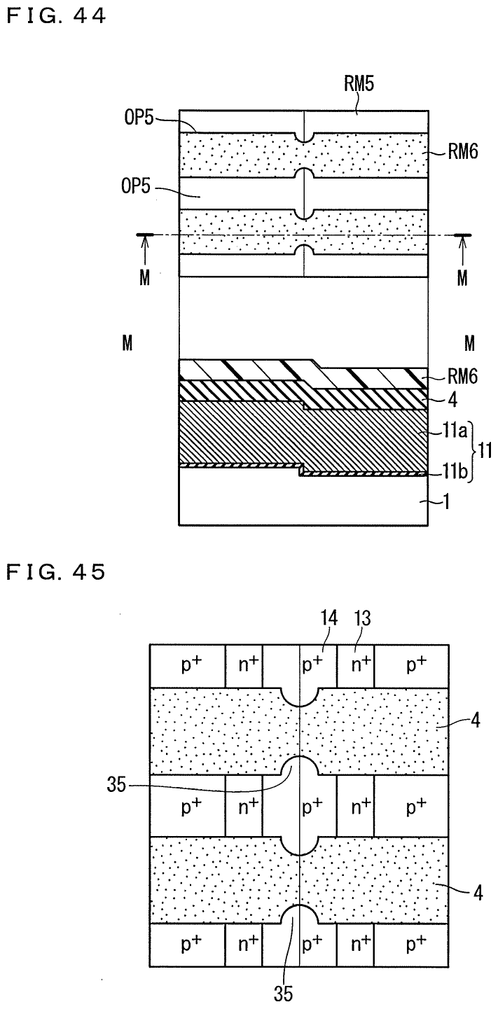

FIG. 45 is a plan view schematically illustrating this process, and a portion corresponding to the step 37 is the narrow width portion 35 in the interlayer insulating film 4 above the active trench gate 11.

As described above, when the step 37 is provided at the position where the narrow width portion 35 is to be formed, the narrow width portion 35 is formed using an existing resist mask patterning the interlayer insulating film 4, so that the manufacturing process can be simplified.

### Other Manufacturing Methods

In the manufacturing method of the fifth preferred embodiment, the method of forming the narrow width portion by providing the step on the first main surface of the semiconductor substrate has been described. However, it is also possible to form the narrow width portion without providing the step.

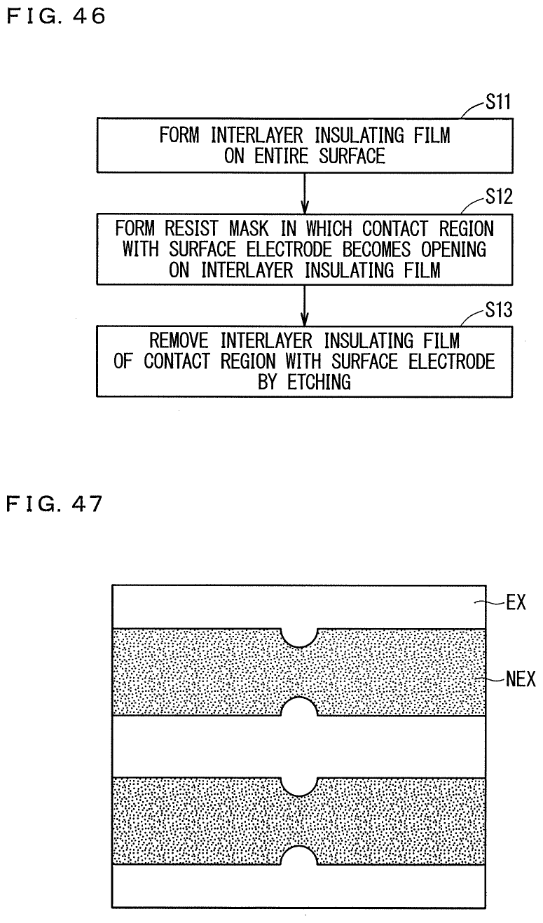

FIG. 46 is a flowchart illustrating a method of manufacturing the RC-IGBT when the narrow width portion is formed without providing the step.

As illustrated in FIG. 46, the interlayer insulating film 4 is formed on the entire first main surface of the semiconductor substrate (step S11). The semiconductor substrate at this stage is a semiconductor substrate in which the n⁺-type source layer 13, the p⁺-type contact layer 14, the gate trench insulating film 11b, and the gate trench electrode 11a are formed in the semiconductor substrate as illustrated in FIG. 42 through the processes described with reference to FIGS. 14 to 17, and the interlayer insulating film 4 can be SiO₂ formed by, for example, CVD.

Subsequently, a resist mask is formed on the interlayer insulating film 4 such that the upper portions of the n⁺-type source layer 13 and the p⁺-type contact layer 14, which are the contact regions with the emitter electrode as the front surface electrode, become the opening (step S12).

In this process, in the resist mask used for the mask processing, a portion of the interlayer insulating film 4 where the narrow width portion 35 is desired to be provided is formed such that the width of the resist is narrowed similarly to the narrow width portion 35. Consequently, the narrow width portion can be formed without providing the step, and an increase in the number of processes by providing the step can be prevented.

At this point, an exposure pattern in the case where the resist material is a positive type is illustrated in FIG. 47. As illustrated in FIG. 47, when the resist material is the positive type, a region NEX that is not exposed has a pattern similar to that of the interlayer insulating film 4 having the narrow width portion 35, and a region EX that is exposed has a pattern similar to that of the contact region with the emitter electrode.

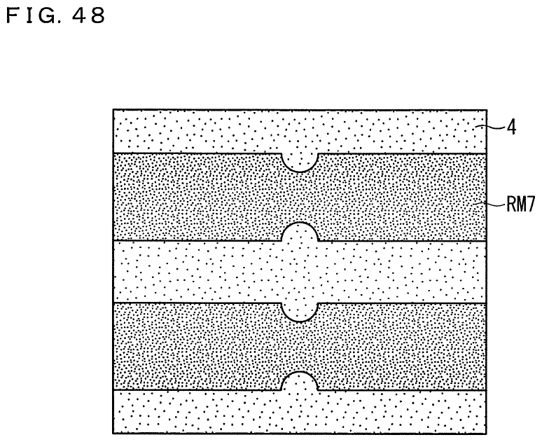

When a positive-type resist material is exposed with such an exposure pattern, a resist mask RM7 as illustrated in FIG. 48 can be obtained. In a case where the resist material is of a negative type, the exposure pattern is obtained by reversing the unexposed region NEX and the exposed region EX in FIG. 47.

Returning to the description of FIG. 46, the resist mask RM7 is used as the etching mask, and the interlayer insulating film 4 in the contact region with the emitter electrode that is the surface electrode is removed by etching (step S13).

### Other Methods for Manufacturing Step

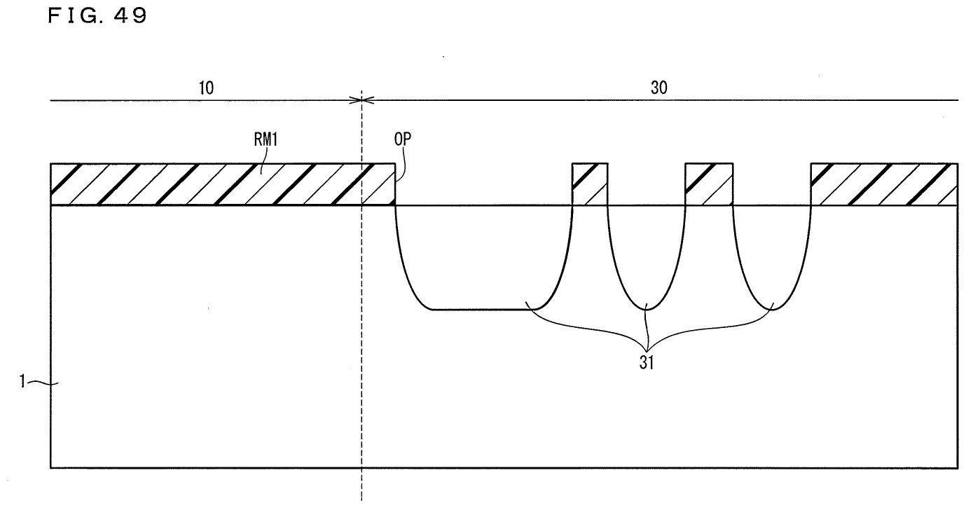

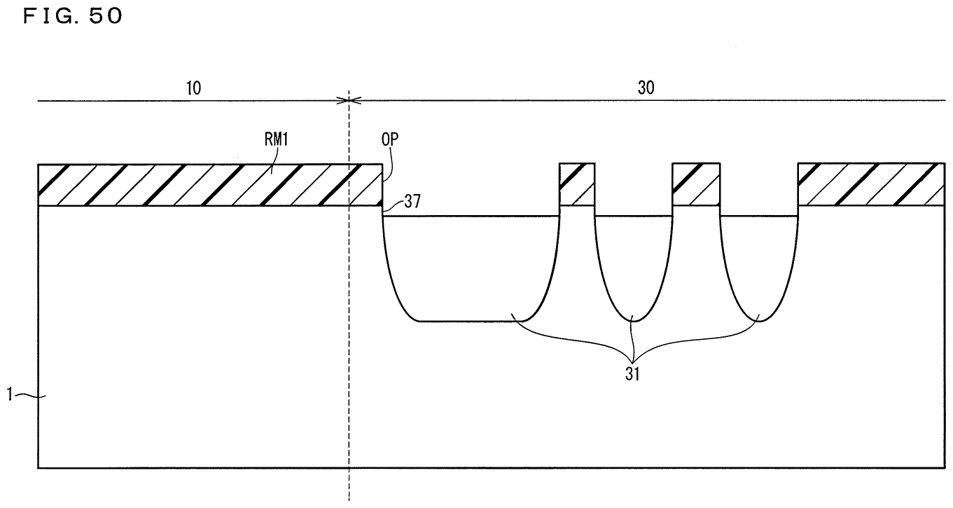

In the second preferred embodiment, the method of manufacturing the step 37 has been described with reference to FIGS. 28 to 32, but the manufacturing method in FIGS. 49 to 51 is exemplified in order to reduce the number of resist masks.

At first, as illustrated in FIG. 49, the resist mask RM1 having the opening OP in the region where the p-type termination well layer 31 is formed is formed, and the p-type impurity is ion-implanted using the resist mask RM1 as the ion implantation mask to form the p-type termination well layer 31. This process is the same as the process described with reference to FIG. 28.

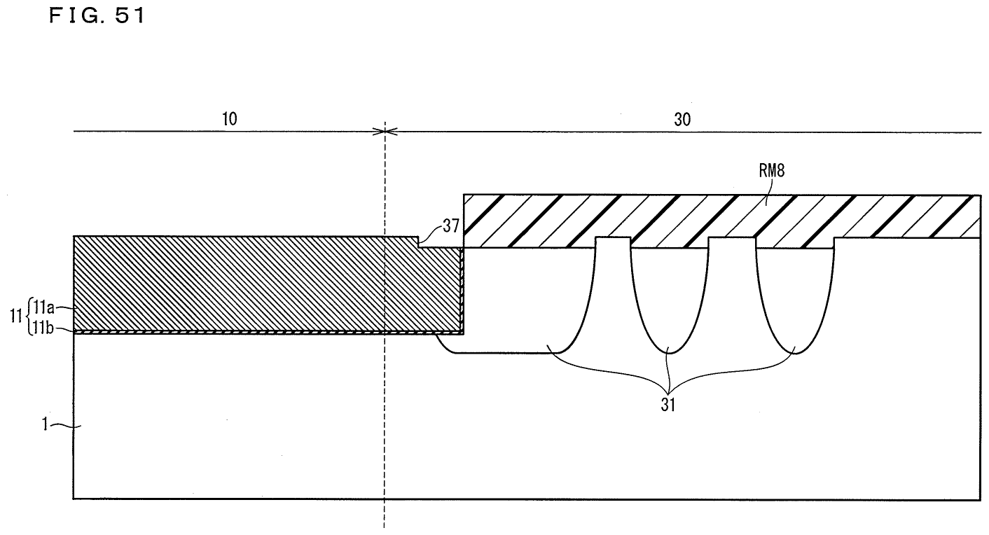

Subsequently, in the process of FIG. 50, the first main surface of the semiconductor substrate is retracted using the resist mask RM1 as the etching mask to form the step 37. In this case, the outermost surface of the p-type termination well layer 31 is also retracted.

Subsequently, in the process illustrated in FIG. 51, the region where the p-type termination well layer 31 is formed is covered with a resist mask RM8, and polysilicon doped with the n-type or p-type impurity by CVD or the like is deposited in the trench in which the gate trench insulating film 11b is formed on the inner wall to form the gate trench electrode 11a, thereby forming the active trench gate 11. FIG. 29 is a view corresponding to the process in FIG. 17.

As described above, when the resist mask forming the p-type termination well layer 31 is also used as the etching mask forming the step 37, the number of resist masks can be reduced, and the manufacturing cost can be reduced.

### Other Application Examples

In the first to fifth preferred embodiments described above, the example in which the present disclosure is applied to the RC-IGBT has been described. However, the present disclosure is not limited to the application to the RC-IGBT, and can also be applied to an IGBT and a MOS field effect transistor (MOSFET). Even in this case, the similar effect as in the case of the application to the RC-IGBT can be obtained.

In the present disclosure, each preferred embodiment can be freely combined, and each preferred embodiment can be appropriately modified or omitted within the scope of the disclosure.

The present disclosure described above will be collectively described as appendixes.

### Appendix 1

A semiconductor device in which a transistor is formed on a semiconductor substrate including a first main surface and a second main surface,
wherein the semiconductor substrate includes a transistor region in which the transistor is formed,
the transistor region includes:
   a first main electrode electrically connected to the first main surface;
   a second main electrode electrically connected to the second main surface;
   a first semiconductor layer of a first conductivity type;
   a second semiconductor layer of a second conductivity type provided closer to the first main surface than the first semiconductor layer;
   a third semiconductor layer of the first conductivity type provided closer to the first main surface than the second semiconductor layer and electrically connected to the first main electrode;
   a trench gate that penetrates the third semiconductor layer and the second semiconductor layer in a thickness direction from the first main surface and reaches an inside of the first semiconductor layer; and
   an interlayer insulating film provided on the trench gate, the interlayer insulating film includes at least one narrow width portion in which a length in a width direction intersecting an extending direction of the trench gate in planar view is partially narrowed, and
the length of the narrow width portion in the width direction is longer than the length of the trench gate in the width direction.

### Appendix 2

The semiconductor device described in Appendix 1, wherein the narrow width portion is formed above a step formed on the first main surface of the semiconductor substrate in a direction intersecting the extending direction of the trench gate in planar view.

### Appendix 3

The semiconductor device described in Appendix 2, wherein
the semiconductor substrate includes a termination region surrounding a cell region including at least the transistor region, and
the step is formed closer to the termination region than a boundary between the transistor region and the termination region.

### Appendix 4

The semiconductor device described in Appendix 2, wherein the step has a height of at least 50 nm.

### Appendix 5

The semiconductor device described in Appendix 1, wherein
the transistor region includes a fourth semiconductor layer of the second conductivity type that is an identical layer as the third semiconductor layer, is provided adjacent to the third semiconductor layer, and is electrically connected to the first main electrode, and
the narrow width portion is formed in a portion where the interlayer insulating film is adjacent to the fourth semiconductor layer in planar view.

### Appendix 6

The semiconductor device described in Appendix 5, wherein the fourth semiconductor layer adjacent to the narrow width portion of the interlayer insulating film is surrounded by the interlayer insulating film and a cross-direction interlayer insulating film that is provided on the adjacent third semiconductor layer and extends in a direction intersecting the extending direction of the trench gate.

### Appendix 7

The semiconductor device described in Appendix 1, wherein
the narrow width portion includes a recess on two side surfaces of the interlayer insulating film in the width direction intersecting the extending direction of the trench gate, and
a portion where the recess is provided has a partially reduced length in the width direction of the interlayer insulating film.

### Appendix 8

The semiconductor device described in Appendix 1, wherein the semiconductor substrate includes a diode region in which a diode is formed.

### Appendix 9

A method of manufacturing a semiconductor device, the method comprising:
(a) a process for preparing a semiconductor substrate including
a first main surface and a second main surface;
a first semiconductor layer of a first conductivity type;
a second semiconductor layer of a second conductivity type provided closer to the first main surface than the first semiconductor layer; and
a third semiconductor layer of a first conductivity type provided closer to the first main surface than the second semiconductor layer;
(b) a process for forming a trench gate that penetrates the third semiconductor layer and the second semiconductor layer in a thickness direction from the first main surface and reaches an inside of the first semiconductor layer; and
(c) a process for forming an interlayer insulating film on the trench gate,
wherein the process (c) includes a process for forming, on the interlayer insulating film, at least one narrow width portion in which a length in a width direction intersecting an extending direction of the trench gate in planar view is partially narrowed, and
the length of the narrow width portion in the width direction is longer than the length of the trench gate in the width direction.

### Appendix 10

The method of manufacturing a semiconductor device described in Appendix 9, further comprising, before the process (c), a process for forming a step on the first main surface of the semiconductor substrate in a direction intersecting the extending direction of the trench gate in planar view.

While the disclosure has been shown and described in detail, the foregoing description is in all aspects illustrative and not restrictive. It is therefore understood that numerous modifications and variations can be devised.

What is claimed is:

1. A semiconductor device in which a transistor is formed on a semiconductor substrate including a first main surface and a second main surface,
wherein the semiconductor substrate includes a transistor region in which the transistor is formed,
the transistor region includes:
a first main electrode electrically connected to the first main surface;
a second main electrode electrically connected to the second main surface;
a first semiconductor layer of a first conductivity type;
a second semiconductor layer of a second conductivity type provided closer to the first main surface than the first semiconductor layer;
a third semiconductor layer of the first conductivity type provided closer to the first main surface than the second semiconductor layer and electrically connected to the first main electrode;
a trench gate that penetrates the third semiconductor layer and the second semiconductor layer in a thickness direction from the first main surface and reaches an inside of the first semiconductor layer; and
an interlayer insulating film provided on the trench gate,
the interlayer insulating film includes at least one narrow width portion in which a length in a width direction intersecting an extending direction of the trench gate in planar view is partially narrowed, and
the length of the narrow width portion in the width direction is longer than the length of the trench gate in the width direction.

2. The semiconductor device according to claim 1, wherein the narrow width portion is formed above a step formed on the first main surface of the semiconductor substrate in a direction intersecting the extending direction of the trench gate in planar view.

3. The semiconductor device according to claim 2, wherein
the semiconductor substrate includes a termination region surrounding a cell region including at least the transistor region, and
the step is formed closer to the termination region than a boundary between the transistor region and the termination region.

4. The semiconductor device according to claim 2, wherein the step has a height of at least 50 nm.

5. The semiconductor device according to claim 1, wherein
the transistor region includes a fourth semiconductor layer of the second conductivity type that is an identical layer as the third semiconductor layer, is provided adjacent to the third semiconductor layer, and is electrically connected to the first main electrode, and
the narrow width portion is formed in a portion where the interlayer insulating film is adjacent to the fourth semiconductor layer in planar view.

6. The semiconductor device according to claim 5, wherein the fourth semiconductor layer adjacent to the narrow width portion of the interlayer insulating film is surrounded by the interlayer insulating film and a cross-direction interlayer insulating film that is provided on the adjacent third semiconductor layer and extends in a direction intersecting the extending direction of the trench gate.

7. The semiconductor device according to claim 1, wherein
the narrow width portion includes a recess on two side surfaces of the interlayer insulating film in the width direction intersecting the extending direction of the trench gate, and
a portion where the recess is provided has a partially reduced length in the width direction of the interlayer insulating film.

8. The semiconductor device according to claim 1, wherein the semiconductor substrate includes a diode region in which a diode is formed.

9. A method of manufacturing a semiconductor device, the method comprising:
(a) a process for preparing a semiconductor substrate including
a first main surface and a second main surface;
a first semiconductor layer of a first conductivity type;
a second semiconductor layer of a second conductivity type provided closer to the first main surface than the first semiconductor layer; and
a third semiconductor layer of a first conductivity type provided closer to the first main surface than the second semiconductor layer;
(b) a process for forming a trench gate that penetrates the third semiconductor layer and the second semiconductor layer in a thickness direction from the first main surface and reaches an inside of the first semiconductor layer; and
(c) a process for forming an interlayer insulating film on the trench gate,
wherein the process (c) includes a process for forming, on the interlayer insulating film, at least one narrow width portion in which a length in a width direction intersecting an extending direction of the trench gate in planar view is partially narrowed, and
the length of the narrow width portion in the width direction is longer than the length of the trench gate in the width direction.

10. The method of manufacturing a semiconductor device according to claim 9, further comprising, before the process (c), a process for forming a step on the first main surface of the semiconductor substrate in a direction intersecting the extending direction of the trench gate in planar view.
